(19) United States
(12) Patent Application Publication
(10) Pub. No.: US 2021/0320171 A1
(43) Pub. Date: Oct. 14, 2021

(54) SUPERJUNCTION SEMICONDUCTOR DEVICE AND METHOD OF MANUFACTURING SUPERJUNCTION SEMICONDUCTOR DEVICE

(71) Applicant: FUJI ELECTRIC CO., LTD., Kawasaki-shi (JP)

(72) Inventor: Takeyoshi NISHIMURA, Matsumoto-city (JP)

(73) Assignee: FUJI ELECTRIC CO., LTD., Kawasaki-shi (JP)

(21) Appl. No.: 17/187,022

(22) Filed: Feb. 26, 2021

(30) Foreign Application Priority Data
Apr. 13, 2020 (JP) 2020-071572
Sep. 18, 2020 (JP) 2020-157344

(51) Int. Cl. H01L 29/06; H01L 29/78; H01L 29/66

(52) U.S. Cl. CPC H01L 29/0634; H01L 29/66734; H01L 29/7813; H01L 29/7811

(57) ABSTRACT

A method of manufacturing a superjunction device, including forming a first semiconductor layer of a first conductivity type on a semiconductor substrate, forming a plurality of first trenches from the first semiconductor layer, forming a second semiconductor layer of the first conductivity type on the first semiconductor layer and in the first trenches, implanting an impurity of a second conductivity type in the second semiconductor layer, thereby forming a plurality of well regions of the second conductivity type, and a parallel pn structure including first and second columns alternating one another repeatedly in a direction parallel to a surface of the semiconductor substrate, forming a plurality of second trenches penetrating through the second semiconductor layer and reaching the first columns, forming a plurality of second semiconductor regions of the second conductivity type in the well regions in the active region, and selectively forming a plurality of first semiconductor regions of the first conductivity type in the second semiconductor regions.

### CROSS REFERENCE TO RELATED APPLICATIONS

This application is based upon and claims the benefit of priority of the prior Japanese Patent Application Nos. 2020-071572 filed on Apr. 13, 2020, and 2020-157344 filed on Sep. 18, 2020, the entire contents of which are incorporated herein by reference.

### BACKGROUND OF THE INVENTION

### 1. Field of the Invention

Embodiments of the invention relate to a superjunction semiconductor device and a method of manufacturing a superjunction semiconductor device.

### 2. Description of the Related Art

Electric vehicles and hybrid vehicles are representative of continuously increasing electrification of vehicles and demand for lower loss (lower ON resistance) of power semiconductors to reduce power consumption is strong. Trench gate metal oxide semiconductor field effect transistors (MOSFETs) are advantageous for reducing ON resistance in lower withstand voltage classes. Furthermore, a superjunction (SJ) structure is effective for reducing the ON resistance of trench gate MOSFETs. A superjunction structure is formed by parallel pn regions in which n-type column regions and p-type column regions are disposed to repeatedly alternate one another in a direction parallel to a main surface of a semiconductor substrate. As methods for forming these parallel pn regions, multistage epitaxial techniques and trench embedding techniques are commonly known.

In a multistage epitaxial technique, the parallel pn regions are formed by the following processes. First, an epitaxial layer is formed on a main surface of a semiconductor substrate. Next, impurities that form n-type regions and p-type regions are ion-implanted into the epitaxial layer. Thereafter as well, epitaxial layer formation and ion implantation are alternately performed repeatedly so that a predetermined parallel pn region thickness corresponding to breakdown voltage of the superjunction semiconductor device is obtained. Thereafter, a heat treatment is performed connecting the n-type regions to one another and connecting the p-type regions to one another, in a depth direction, thereby forming the parallel pn regions (for example, refer to Japanese Laid-Open Patent Publication No. 2016-21547).

In a trench embedding technique, the parallel pn regions are formed by the following processes. First, an n-type epitaxial layer is formed on a main surface of a semiconductor substrate. Next, trenches for forming p-type column regions are formed in the n-type epitaxial layer. Regions free of the trenches become n-type column regions. A depth of the trenches is set to a depth that obtains a predetermined parallel pn region thickness that corresponds to the breakdown voltage of the superjunction semiconductor device. Thereafter, a p-type epitaxial layer is embedded in the trenches, whereby the parallel pn regions are formed (for example, refer to Japanese Laid-Open Patent Publication No. 2016-21547 and Japanese Laid-Open Patent Publication No. 2004-241768).

### SUMMARY OF THE INVENTION

According to an embodiment of the invention, a method of manufacturing a superjunction semiconductor device having an active region through which a current flows, and a termination structure region disposed at an outer periphery of the active region, the method including: preparing a semiconductor substrate of a first conductivity type, the semiconductor substrate having a first surface and a second surface opposite to each other; forming a first semiconductor layer of the first conductivity type on the first surface of the semiconductor substrate, the first semiconductor layer having an impurity concentration lower than an impurity concentration of the semiconductor substrate; forming a plurality of first trenches from a surface of the first semiconductor layer; forming a second semiconductor layer of the first conductivity type on the surface of the first semiconductor layer and in the first trenches, the second semiconductor layer having an impurity concentration lower than the impurity concentration of the first semiconductor layer; implanting an impurity of a second conductivity type in the second semiconductor layer, thereby forming a plurality of well regions of the second conductivity type, and a parallel pn structure including a plurality of first columns of the first conductivity type and a plurality of second columns of the second conductivity type, the first columns and the second columns alternating one another repeatedly in a direction parallel to the first surface of the semiconductor substrate, each of the second columns having a top surface in contact with a bottom surface of one of the well regions; forming a plurality of second trenches each penetrating through the second semiconductor layer and reaching one of the first columns; forming a plurality of second semiconductor regions of the second conductivity type each in one of the well regions on a surface thereof and in the active region; forming a gate insulating film and a gate electrode in each of the second trenches; and selectively forming a plurality of first semiconductor regions of the first conductivity type in the second semiconductor regions of the active region, each first semiconductor region being formed in one of the second semiconductor regions at a surface thereof.

Objects, features, and advantages of the present invention are specifically set forth in or will become apparent from the following detailed description of the invention when read in conjunction with the accompanying drawings.

### BRIEF DESCRIPTION OF THE DRAWINGS

FIG. 1 is a cross-sectional view depicting a structure of a SJ-MOSFET according to an embodiment.

FIG. 2A is a cross-sectional view depicting another structure of the SJ-MOSFET according to the embodiment.

FIG. 2B is a cross-sectional view depicting another structure of the SJ-MOSFET according to the embodiment.

FIG. 2C is a cross-sectional view depicting another structure of the SJ-MOSFET according to the embodiment.

FIG. 2D is a cross-sectional view depicting another structure of the SJ-MOSFET according to the embodiment.

FIG. 3 is a plan view depicting the structure of the SJ-MOSFET according to the embodiment, along cutting line A-A′ in FIG. 1.

FIG. 4 is a cross-sectional view depicting a state of the SJ-MOSFET according to the embodiment during manufacture by a first method of manufacturing.

FIG. 5 is a cross-sectional view depicting a state of the SJ-MOSFET according to the embodiment during manufacture by the first method of manufacturing.

FIG. 6 is a cross-sectional view depicting a state of the SJ-MOSFET according to the embodiment during manufacture by the first method of manufacturing.

FIG. 7 is a cross-sectional view depicting a state of the SJ-MOSFET according to the embodiment during manufacture by the first method of manufacturing.

FIG. 8 is a cross-sectional view depicting a state of the SJ-MOSFET according to the embodiment during manufacture by the first method of manufacturing.

FIG. 9A is a cross-sectional view depicting a state of the SJ-MOSFET according to the embodiment during manufacture by the first method of manufacturing.

FIG. 9B is a cross-sectional view depicting a state of the SJ-MOSFET according to the embodiment during manufacture by the first method of manufacturing.

FIG. 9C is a cross-sectional view depicting a state of the SJ-MOSFET according to the embodiment during manufacture by the first method of manufacturing.

FIG. 10A is a cross-sectional view depicting a state of the SJ-MOSFET according to the embodiment during manufacture by the first method of manufacturing.

FIG. 10B is a cross-sectional view depicting a state of the SJ-MOSFET according to the embodiment during manufacture by the first method of manufacturing.

FIG. 10C is a cross-sectional view depicting a state of the SJ-MOSFET according to the embodiment during manufacture by the first method of manufacturing.

FIG. 11 is a cross-sectional view depicting a state of the SJ-MOSFET according to the embodiment during manufacture by the first method of manufacturing.

FIG. 12 is a cross-sectional view depicting a state of the SJ-MOSFET according to the embodiment during manufacture by the first method of manufacturing.

FIG. 13 is a cross-sectional view depicting a state of the SJ-MOSFET according to the embodiment during manufacture by the first method of manufacturing.

FIG. 14 is a cross-sectional view depicting a state of the SJ-MOSFET according to the embodiment during manufacture by the first method of manufacturing.

FIG. 15 is a cross-sectional view depicting a state of the SJ-MOSFET according to the embodiment during manufacture by the first method of manufacturing.

FIG. 16 is a cross-sectional view depicting a state of the SJ-MOSFET according to the embodiment during manufacture by the first method of manufacturing.

FIG. 17 is a cross-sectional view depicting a state of the SJ-MOSFET according to the embodiment during manufacture by the first method of manufacturing.

FIG. 18 is a cross-sectional view depicting a state of the SJ-MOSFET according to the embodiment during manufacture by the first method of manufacturing.

FIG. 19 is a cross-sectional view depicting a state of the SJ-MOSFET according to the embodiment during manufacture by the first method of manufacturing.

FIG. 20 is a cross-sectional view depicting a state of the SJ-MOSFET according to the embodiment during manufacture by the first method of manufacturing.

FIG. 21 is a cross-sectional view depicting a state of the SJ-MOSFET according to the embodiment during manufacture by the first method of manufacturing.

FIG. 22 is a cross-sectional view depicting a state of the SJ-MOSFET according to the embodiment during manufacture by the first method of manufacturing.

FIG. 23 is a cross-sectional view depicting a state of the SJ-MOSFET according to the embodiment during manufacture by the first method of manufacturing.

FIG. 24 is a cross-sectional view depicting a state of the SJ-MOSFET according to the embodiment during manufacture by the first method of manufacturing.

FIG. 25 is a cross-sectional view depicting a state of the SJ-MOSFET according to the embodiment during manufacture by the first method of manufacturing.

FIG. 26 is a cross-sectional view of a state of the SJ-MOSFET according to the embodiment during manufacture by a second method of manufacturing.

FIG. 27 is a cross-sectional view of a state of the SJ-MOSFET according to the embodiment during manufacture by the second method of manufacturing.

FIG. 28 is a cross-sectional view of a state of the SJ-MOSFET according to the embodiment during manufacture by the second method of manufacturing.

FIG. 29 is a cross-sectional view of a state of the SJ-MOSFET according to the embodiment during manufacture by the second method of manufacturing.

FIG. 30 is a cross-sectional view of a state of the SJ-MOSFET according to the embodiment during manufacture by the second method of manufacturing.

FIG. 31 is a cross-sectional view of a state of the SJ-MOSFET according to the embodiment during manufacture by a third method of manufacturing.

FIG. 32 is a cross-sectional view of a state of the SJ-MOSFET according to the embodiment during manufacture by the third method of manufacturing.

FIG. 33 is a cross-sectional view of a state of the SJ-MOSFET according to the embodiment during manufacture by the third method of manufacturing.

FIG. 34 is a cross-sectional view of a state of the SJ-MOSFET according to the embodiment during manufacture by the third method of manufacturing.

FIG. 35 is a cross-sectional view of a state of the SJ-MOSFET according to the embodiment during manufacture by the third method of manufacturing.

FIG. 36 is a cross-sectional view of a state of the SJ-MOSFET according to the embodiment during manufacture by the third method of manufacturing.

FIG. 37 is a cross-sectional view of a state of the SJ-MOSFET according to the embodiment during manufacture by the third method of manufacturing.

FIG. 38 is a cross-sectional view of a state of the SJ-MOSFET according to the embodiment during manufacture by the third method of manufacturing.

FIG. 39 is a cross-sectional view of a state of the SJ-MOSFET according to the embodiment during manufacture by the third method of manufacturing.

### DETAILED DESCRIPTION OF THE INVENTION

First, problems associated with the conventional techniques are discussed. In the multistage epitaxial technique, the possibility of characteristics variation increases due to variations in dimensions and/or positioning from repeatedly performing mask formation by a photolithographic technique and ion implantation, for each epitaxial growth. Furthermore, due to mutual diffusion of the parallel pn regions as a consequence of a thermal history for each epitaxial growth, concentration compensation between an n-type column region and an adjacent p-type column region may occur, whereby the ON resistance may increase. Further, there are numerous processes, thereby increasing lead time and manufacturing cost.

Further, in the trench embedding technique, when the p-type epitaxial layer is embedded in the trenches, the p-type epitaxial layer formed on the surface of the n-type epitaxial layer that forms the n-type column regions is removed by a chemical mechanical polisher (CMP) process and thereafter, an n-type epitaxial layer is formed on the surface. A reason for removing the p-type epitaxial layer is that when a p-type layer is present in the edge termination region, the breakdown voltage cannot be sustained. Therefore, the trench embedding technique requires CMP equipment and due to variation of a polishing amount by the CMP process, characteristics may vary. Further, as compared to n-type epitaxial growth, p-type epitaxial growth has greater variation of impurity concentration and requires impurity concentration control. Furthermore, since a high-concentration p-type epitaxial layer and an n-type drift layer form a junction, a gradient of the impurity concentration is large, the depletion layer does not spread easily, and the breakdown voltage may decrease.

Embodiments of a superjunction semiconductor device and a method of manufacturing a superjunction semiconductor device according to the present invention are described in detail with reference to the accompanying drawings. In the present description and accompanying drawings, layers and regions prefixed with n or p mean that majority carriers are electrons or holes. Additionally, + or − appended to n or p means that the impurity concentration is higher or lower, respectively, than layers and regions without + or −. Cases where symbols such as n's and p's that include + or − are the same indicate that concentrations are close and therefore, the concentrations are not necessarily equal. In the description of the embodiments below and the accompanying drawings, main portions that are identical will be given the same reference numerals and will not be repeatedly described.

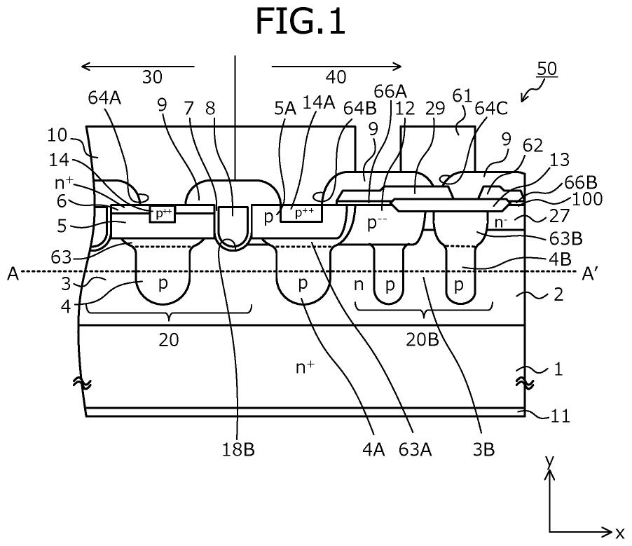

A superjunction semiconductor device according to the invention is described taking a SJ-MOSFET as an example. FIG. 1 is a cross-sectional view depicting a structure of a SJ-MOSFET according to an embodiment.

A superjunction semiconductor device (SJ-MOSFET) 50 depicted in FIG. 1 is a SJ-MOSFET that has metal oxide semiconductor (MOS) gates on a front side (side having later-described p-type base regions 5) of a semiconductor base (silicon base: semiconductor chip) containing silicon (Si). The SJ-MOSFET 50 includes an active region 30 and an edge termination region 40 surrounding a periphery of the active region 30. The active region 30 is a region through which current passes during an ON state. The edge termination region 40 includes a breakdown voltage sustaining region that mitigates electric field on a semiconductor-base front surface side of a drift region and that sustains breakdown voltage. A border between the active region 30 and the edge termination region 40 is a center of a trench 18B having a later-described n⁺-type source region 6 on only one side thereof. In the active region 30 depicted in FIG. 1, only one unit cell (functional unit of a device element) is depicted and other unit cells adjacent thereto are not depicted. A unit cell is from a center of one trench 18B to a center of another trench 18B adjacent thereto.

An n⁺-type semiconductor substrate (semiconductor substrate of a first conductivity type) 1 is a silicon single crystal substrate, for example, doped with arsenic (As) or phosphorus (P). On the n⁺-type semiconductor substrate 1, an n-type drift layer (first semiconductor layer of a first conductivity type) 2 is provided. The n-type drift layer 2 has an impurity concentration lower than an impurity concentration of the n⁺-type semiconductor substrate 1 and, for example, is a low-concentration n-type layer doped with phosphorus.

Hereinafter, the n⁺-type semiconductor substrate 1 and the n-type drift layer 2 combined are regarded as the semiconductor base. Between the n⁺-type semiconductor substrate 1 and the n-type drift layer 2, an n-type buffer layer (not depicted) having an impurity concentration lower than the impurity concentration of the n-type drift layer 2 may be disposed. The n-type buffer layer, for example, is a low-concentration n-type layer doped with phosphorus. In the semiconductor base, at a front surface thereof, a MOS gate structure (device element structure) is formed. Further, on a back surface of the semiconductor base, a back electrode 11 that forms a drain electrode is provided.

In the active region 30 of the SJ-MOSFET 50, a parallel pn region 20 is provided in which n-type column regions 3 and p-type column regions 4 are disposed to repeatedly alternate one another. In the edge termination region 40 as well, a later-described parallel pn region 20B may be provided.

In FIG. 1, a direction along which the n-type column regions 3 and the p-type column regions 4 of the parallel pn region 20 are disposed repeatedly alternating one another is an x direction. On the p-type column regions 4 of the active region 30, p-type well regions 63 are provided. Bottom surfaces of the p-type well regions 63 of the active region 30 are in contact with top surfaces of the p-type column regions 4. The p-type well regions 63 and the p-type column regions 4 of the active region 30 are provided from a surface of an n⁻-type epitaxial layer 27 provided on a top surface of the n-type drift layer 2, the p-type well regions 63 and the p-type column regions 4 being provided so as not to reach a surface of the n⁺-type semiconductor substrate 1. A width of a top surface of each of the p-type well regions 63 is greater than a width of each of the p-type column regions 4. Here, a surface of the n⁻-type epitaxial layer 27 provided on the top surface of the n-type drift layer 2 (on a first main surface of the semiconductor base) is assumed as a top surface 100.

The width of the top surface of each of the p-type well regions 63 is greater than the width of each of the p-type column regions 4, whereby an effect of improving reverse breakdown voltage (BVDSS: drain-source breakdown voltage) is obtained. As described hereinafter, the n-type column regions 3 and the p-type column regions 4 in the active region 30 and in the edge termination region 40, for example, each have a stripe-shape in a plan view thereof. When the p-type column regions 4 each have a striped-shape, the p-type well regions 63 each have a stripe-shape in a plan view thereof.

The n-type column regions 3 have an impurity concentration lower than the impurity concentration of the n⁺-type semiconductor substrate 1. An impurity concentration of the p-type column regions 4 and an impurity concentration of the p-type well regions 63 may be equal to one another. Further, the impurity concentration of the n-type column regions 3 and the impurity concentration of the p-type column regions 4 may be equal to one another.

P-type base regions (second semiconductor regions of a second conductivity type) 5 are selectively provided in the active region 30, at the top surface 100 (above the first main surface of the semiconductor base). The p-type base regions 5 are provided overlapping the p-type well regions 63, respectively. The bottom surfaces of the p-type well regions 63 are provided at positions deeper in a y direction (the depth direction) depicted in FIG. 1 than are positions of bottom surfaces of the p-type base regions 5. The p-type base regions 5 have an impurity concentration higher than the impurity concentration of the p-type well regions 63. Further, the impurity concentration of the p-type base regions 5 is higher than the impurity concentration of the p-type column regions 4.

The n⁺-type source regions (first semiconductor regions of the first conductivity type) 6 are selectively provided in the p-type base regions 5, at surfaces thereof, in the active region 30. In the p-type base regions 5, at the surfaces thereof, in the active region 30, p⁺⁺-type contact regions 14 may be selectively provided in contact with the n⁺-type source regions 6.

Trench structures are formed in the active region 30 and at the border between the active region 30 and the edge termination region 40. In particular, the trenches 18B (second trenches) penetrate the p-type base regions 5, later-described p-type base regions 5A, and the n⁺-type source regions 6 from the top surface 100 and reach the n-type column regions 3.

The p-type base regions 5 and the n⁺-type source regions 6 are in contact with sidewalls of the trenches 18B provided in the active region 30. Further, of the sidewalls of each of the trenches 18B provided at the border between the active region 30 and the edge termination region 40, a first sidewall in the active region 30 is in contact with one of the p-type base regions 5 and one of the n⁺-type source regions 6, and a second sidewall thereof in the edge termination region 40 is in contact with one of the later-described p-type base regions 5A. The trenches 18B are not provided in the edge termination region 40.

The trenches 18B of the active region 30 are provided between the p-type base regions 5 that are selectively provided; and each of the trenches 18B at the border between the active region 30 and the edge termination region 40 is provided between one of the p-type base regions 5 and one of the p-type base regions 5A. A shape of the trenches 18B in a plan view thereof, for example, is a stripe shape extending in a viewing direction (z direction) of FIG. 1.

In the trenches 18B, gate insulating films 7 are formed along inner walls of the trenches 18B. Gate electrodes 8 are provided on the gate insulating films 7 in the trenches 18B. The gate electrodes 8 are insulated from the n-type column regions 3 (the n-type drift layer 2) and the p-type base regions 5 by the gate insulating films 7. A portion of the gate electrodes 8 may be provided with gate wiring (not depicted) protruding from tops (sides where a later-described source electrode 10 is provided) of the trenches 18B, toward the source electrode 10. At a lower portion of the gate wiring, the gate insulating films 7 are provided. At an upper portion of the gate wiring, an interlayer insulating film 9 is provided.

The interlayer insulating film 9 is provided on the top surface 100 so as to cover the top surfaces of the gate electrodes 8 embedded in the trenches 18B. An insulating film (not depicted) is provided between the gate electrodes 8 and the interlayer insulating film 9 (a border of the interlayer insulating film 9 covering the gate electrodes 8 and the gate insulating films 7 formed along the inner walls of the trenches 18B, and a border of the insulating film provided between the interlayer insulating film 9 and the gate electrodes 8 are not depicted). Between adjacent trenches 18B of the trenches 18B, contact holes 64A are provided in the interlayer insulating film 9 that covers the top surfaces of the gate electrodes 8 embedded in the trenches 18B of the active region 30, whereby the n⁺-type source regions 6 and the p⁺⁺-type contact regions 14 are exposed. Similarly, the contact holes 64A are provided in the interlayer insulating film 9 covering the top surfaces of the gate electrodes 8 respectively embedded in the trenches 18B provided at the border between the active region 30 and the edge termination region 40 and in the trenches 18B adjacent thereto in the active region 30, thereby exposing the n⁺-type source regions 6 and the p⁺⁺-type contact regions 14. Hereinafter, the insulating film (not depicted) provided between the gate electrodes 8 and the interlayer insulating film 9 is not further described.

The source electrode 10 is provided on a top surface of the interlayer insulating film 9 and is electrically connected to the n⁺-type source regions 6 and the p⁺⁺-type contact regions 14 via the contact holes 64A formed in the interlayer insulating film 9 and in an insulating film (not depicted) provided on a bottom surface of the interlayer insulating film 9. Hereinafter, the insulating film (not depicted) provided on the bottom surface of the interlayer insulating film 9 is not further described. The source electrode 10 is electrically insulated from the gate electrodes 8 by the interlayer insulating film 9. Between the source electrode 10 and the interlayer insulating film 9, for example, a barrier metal (not depicted) that prevents diffusion of metal atoms from the source electrode 10 to the gate electrodes 8 may be provided. On the source electrode 10, a protective film (not depicted) such as a passivation film containing, for example, a polyimide is selectively provided. In an opening provided in the protective film, such as a passivation film, provided on the source electrode 10, a region in which the source electrode 10 is exposed is a source pad region (not depicted).

Further, in the edge termination region 40 that sustains the breakdown voltage, at a side thereof closest to the active region 30, a p-type column region 4A having a width equal to the width of each of the p-type column regions 4 of the active region 30 is provided. The p-type column regions 4 and each p-type column region 4A may have depths equal to one another in the y direction (the depth direction) depicted in FIG. 1. On each p-type column region 4A, a p-type well region 63A is provided. A top surface of the p-type column region 4A and a bottom surface of the p-type well region 63A are in contact with each other. The p-type column regions 4 and the p-type column regions 4A suffice to have impurity concentrations equal to one another and the p-type well regions 63 and the p-type well regions 63A also may have impurity concentrations equal to one another.

The p-type base regions 5A are provided so as to overlap the p-type well regions 63A and are in contact with a sidewall of the trenches 18B provided at the border between the active region 30 and the edge termination region 40. The bottom surfaces of the p-type well regions 63A are provided at positions deeper than bottom surfaces of the p-type base regions 5A, in the y direction (the depth direction) depicted in FIG. 1. The p-type base regions 5A may be formed at a depth equal to a depth of the p-type base regions 5 of the active region 30, in the y direction (the depth direction) depicted in FIG. 1. Further, the p-type well regions 63A may be formed at a depth equal to a depth of the p-type well regions 63 of the active region 30, in the y direction (the depth direction) depicted in FIG. 1.

The p-type base regions 5A have an impurity concentration equal to the impurity concentration of the p-type base regions 5. Further, the impurity concentration of the p-type base regions 5A is higher than the impurity concentration of the p-type well regions 63A. P⁺⁺-type contact regions 14A having an impurity concentration higher than the impurity concentration of the p-type base regions 5A may be selectively provided in the p-type base regions 5A, at surfaces thereof.

The parallel pn region 20B is provided closer to an outer peripheral side of the SJ-MOSFET 50 than are the p-type column regions 4A of the edge termination region 40. In the parallel pn region 20B, n-type column regions 3B and p-type column regions 4B are disposed repeatedly alternating one another. A direction in which the n-type column regions 3B and the p-type column regions 4B are disposed repeatedly alternating one another is a same direction as the direction in which the n-type column regions 3 and the p-type column regions 4 of the active region 30 are arranged repeatedly alternating one another.

In the parallel pn region 20B of the edge termination region 40, a sum of a width of an n-type column and a width of a p-type column adjacent thereto is less than a sum of a width of an n-type column and a width of a p-type column adjacent thereto in the parallel pn region 20 of the active region 30. Here, the sum of the width of an n-type column and the width of a p-type column adjacent thereto is a repetition pitch. Therefore, a width of the n-type column regions 3B and a width of the p-type column regions 4B of the edge termination region 40 are narrower than a width of the n-type column regions 3 and a width of the p-type column regions 4 of the active region 30. As a result, in the edge termination region 40, a depletion layer spreads easily, thereby enabling the breakdown voltage of the edge termination region 40 to be higher than the breakdown voltage of the active region 30.

In the edge termination region 40, a p⁻⁻-type RESURF region 12 is provided. The p⁻⁻-type RESURF region 12 extends from the border between the active region 30 and the edge termination region 40 to beneath a later-described field plate 29 and a field oxide film 13. The p⁻⁻-type RESURF region 12 has a ring shape in a plan view thereof.

The p⁻⁻-type RESURF region 12 is provided deeper in the y direction (the depth direction) depicted in FIG. 1 than are the p-type base regions 5A. The p⁻⁻-type RESURF region 12 has an impurity concentration lower than the impurity concentration of the p-type well regions 63A. Therefore, the p-type well regions 63A, the p-type base regions 5A, and the p⁺⁺-type contact regions 14A are provided in the p⁻⁻-type RESURF region 12. The p⁻⁻-type RESURF region 12 is in contact with the trenches 18B provided at the border between the active region 30 and the edge termination region 40.

Concentration of electric field applied to the p-type base regions 5A, at ends thereof facing the outer peripheral side of the SJ-MOSFET 50, is mitigated by the p⁻⁻-type RESURF region 12, enabling the breakdown voltage of the edge termination region 40 to be raised. In the parallel pn region 20B of the edge termination region 40, top surfaces the n-type column region 3B and the p-type column region 4B closest to the active region 30 are in contact with a bottom surface of the p⁻-type RESURF region 12.

In the parallel pn region 20B, a top surface of an outermost p-type column region 4B at an outermost peripheral side of the SJ-MOSFET 50 is in contact with a bottom surface of a p-type well region 63B at the outermost peripheral side of the SJ-MOSFET 50. Between the p-type well region 63B at the outermost peripheral side of the SJ-MOSFET 50 and the p⁻⁻-type RESURF region 12, in the x direction depicted in FIG. 1, a later-described n⁻-type epitaxial layer 27 is provided.

Further, in the edge termination region 40, the n⁻-type epitaxial layer (second semiconductor layer of the first conductivity type) 27 is provided on the surface of the n-type drift layer 2 (semiconductor base). As described hereinafter, the n⁻-type epitaxial layer 27 is formed in an entire area of the surface of the n-type drift layer 2. The n⁺-type source regions 6, the p^{+±}-type contact regions 14, 14A, and respective upper portions of the p-type well regions 63, 63A, 63B, the p-type base regions 5, 5A, and the p⁻⁻-type RESURF region 12 are provided in a surface layer of the n⁻-type epitaxial layer 27.

Further, the n⁻-type epitaxial layer 27 has an impurity concentration lower than the impurity concentration of the n-type drift layer 2. Therefore, a p-type impurity implanted by ion implantation diffuses more easily in the n⁻-type epitaxial layer 27 than the n-type drift layer 2 by a heat treatment after the ion implantation and diffusion in the n-type drift layer 2 becomes difficult. As a result, diffusion of the p-type base regions 5 by a heat treatment after ion implantation is easily controlled and variation of gate threshold voltage Vth may be suppressed.

In the x direction depicted in FIG. 1, the field oxide film 13 is provided from the outer peripheral side of the SJ-MOSFET 50 to span the n⁻-type epitaxial layer 27, the p-type well region 63B, and the p⁻⁻-type RESURF region 12. The field oxide film 13 may be provided to a position deep from the top surface 100 in the y direction depicted in FIG. 1. A portion of a bottom surface of the field oxide film 13, from one end thereof facing the active region 30 is continuously covered by the p⁻⁻-type RESURF region 12 therebelow. On the bottom surface of the field oxide film 13, the p⁻⁻-type RESURF region 12, the p-type well region 63B, and the n⁻-type epitaxial layer 27 are provided, and on a portion of the bottom surface of the field oxide film 13, from another end thereof, the n⁻-type epitaxial layer 27 is provided continuously.

On top surfaces of the p⁻⁻-type RESURF region 12, the p-type well regions 63A, and the p-type base regions 5A, an insulating film 66A connected to the one end of the field oxide film 13 facing the active region 30 is provided and on a top surface of the n⁻-type epitaxial layer 27, an insulating film 66B connected to the other end of the field oxide film 13 is provided. The insulating films 66A, 66B may be formed by a process for the gate insulating films 7.

The field plate 29 is provided on the field oxide film 13 and on a top surface of the insulating film 66A connected to the one end of the field oxide film 13 facing the active region 30. The field plate 29 is electrically connected to the gate electrodes 8 and also has a function of gate wiring.

A channel stopper 62 is provided on the field oxide film 13 and a top surface of the insulating film 66B connected to the other end of the field oxide film 13. The field plate 29 and the channel stopper 62 are provided on the field oxide film 13, separate from each other by an interval. The interlayer insulating film 9 is provided so as to cover the field oxide film 13, the field plate 29, and the channel stopper 62. An insulating film (not depicted) is provided between the interlayer insulating film 9 and the field plate 29 and between the interlayer insulating film 9 and the channel stopper 62. Hereinafter, the insulating film (not depicted) provided between the interlayer insulating film 9 and the field plate 29 and between the interlayer insulating film 9 and the channel stopper 62 is not further described.

In the interlayer insulating film 9, between a portion thereof provided covering the field plate 29 and each portion thereof covering the top surfaces of the gate electrodes 8 embedded in the trenches 18B provided at the border between the active region 30 and the edge termination region 40, contact holes 64B are provided, exposing the p⁺⁺-type contact regions 14A.

In the interlayer insulating film 9 covering the field oxide film 13, the field plate 29, and the channel stopper 62, a contact hole 64C is provided, exposing the field plate 29.

The source electrode 10 provided on the top surface of the interlayer insulating film 9 extends from the active region 30 to the top surface of a portion of the edge termination region 40 and via the contact holes 64B formed in the interlayer insulating film 9, is electrically connected to the p⁺⁺-type contact regions 14A and the p-type base regions 5A.

A metal gate runner 61 is electrically connected to the field plate 29 via the contact hole 64C formed in the interlayer insulating film 9. Portions of the interlayer insulating film 9 above the p⁻⁻-type RESURF region 12, the field oxide film 13, the field plate 29, the channel stopper 62, and the edge termination region 40 may be provided in a ring shape at an outer periphery of the SJ-MOSFET 50. The metal gate runner 61 is electrically insulated from the source electrode 10.

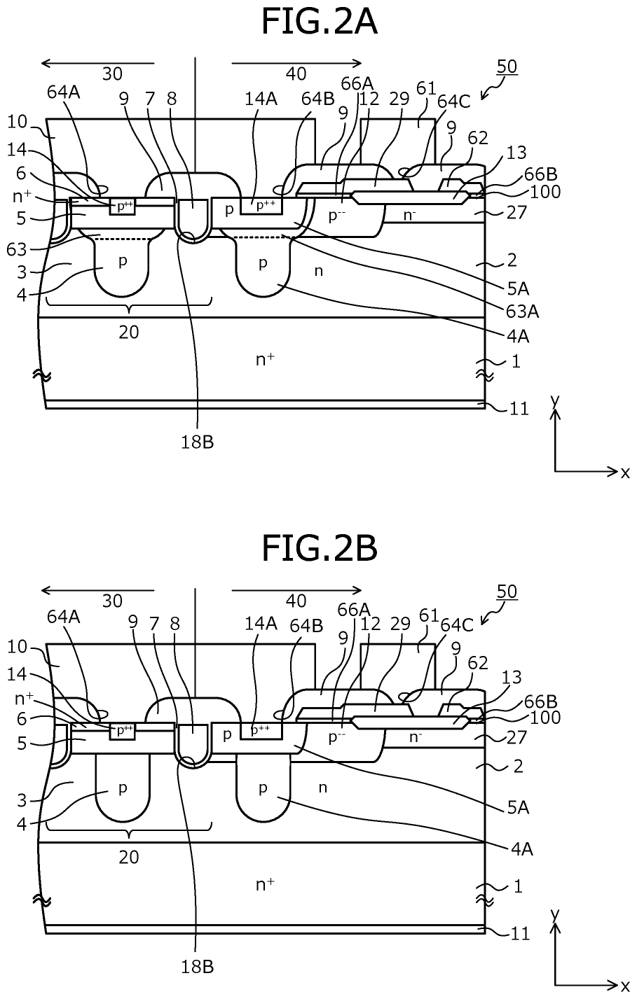

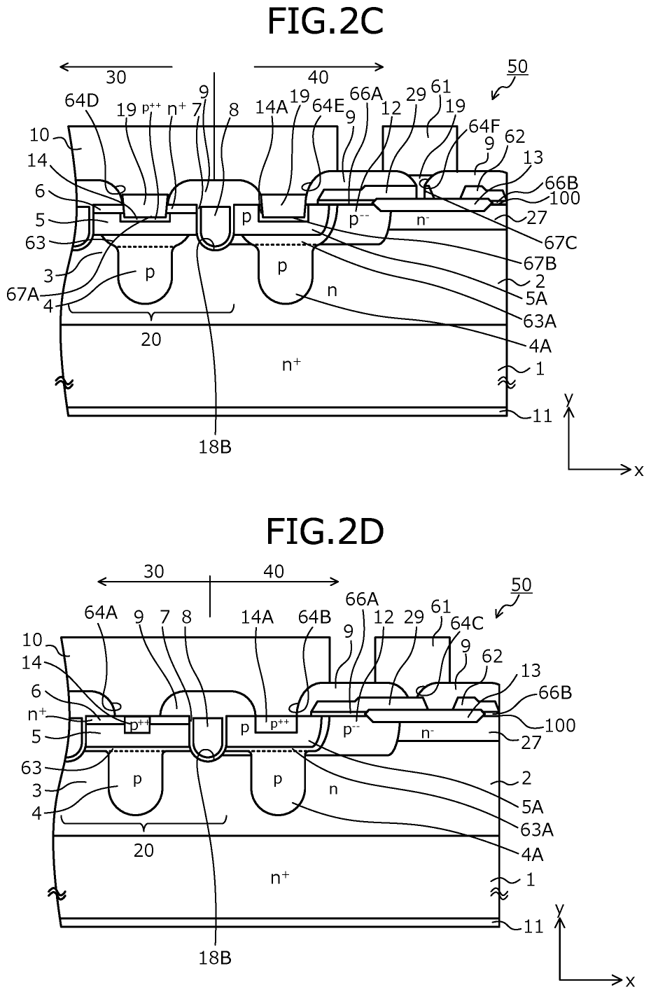

FIG. 2A is a cross-sectional view depicting another structure of the SJ-MOSFET 50 according to the embodiment. FIG. 2A differs from FIG. 1 in that the parallel pn region 20B closer to the outer periphery of the SJ-MOSFET 50 than are the p-type column regions 4A of the edge termination region 40 is not provided. In an instance in which the parallel pn region 20B is not provided, due to the n⁻-type epitaxial layer 27, a depletion layer that extends from a pn junction between the n⁻-type epitaxial layer 27 and the p⁻⁻-type RESURF region 12 spreads to a side of the n⁻-type epitaxial layer 27 facing the outer periphery of the SJ-MOSFET 50, whereby the breakdown voltage of the SJ-MOSFET 50 may be improved.

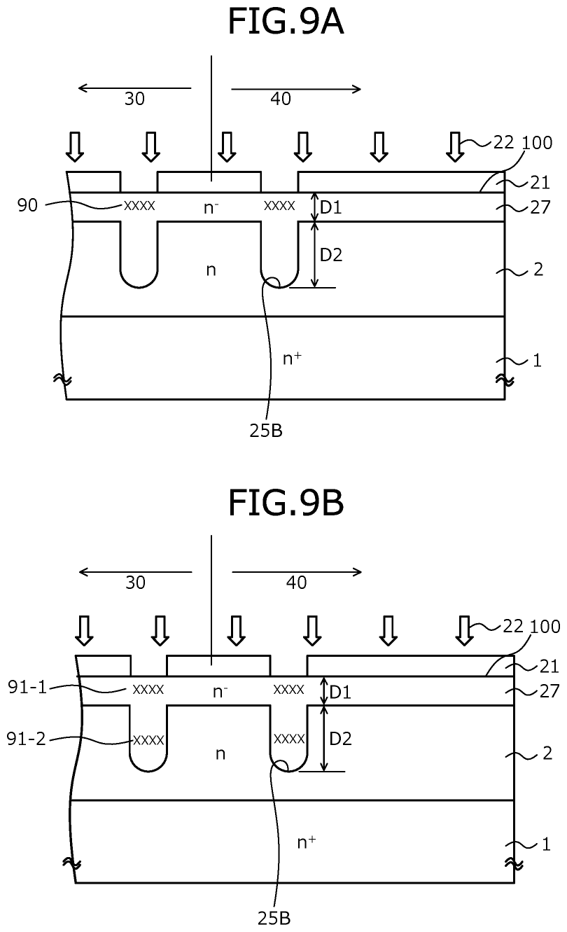

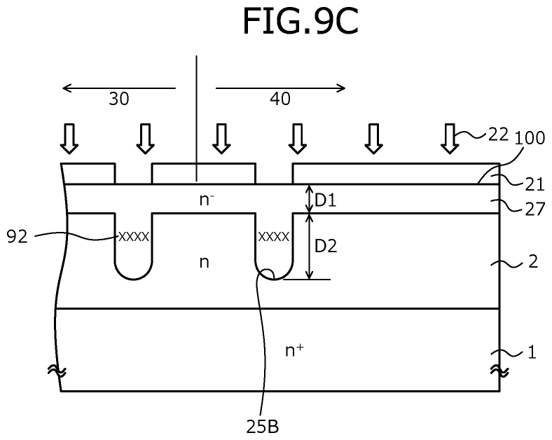

FIG. 2B is a cross-sectional view depicting another structure of the SJ-MOSFET 50 according to the embodiment. FIG. 2B differs from FIG. 2A in that the p-type well regions 63 in contact with the top surfaces of the p-type column regions 4 of the active region 30 and the p-type well regions 63A in contact with the top surfaces of the p-type column regions 4A of the edge termination region 40 are not provided. In FIG. 2B, the p-type base regions 5 are provided on the top surfaces of the p-type column regions 4 of the active region 30. The top surfaces of the p-type column regions 4 of the active region 30 are in contact with the bottom surfaces of the p-type base regions 5. Further, the p-type base regions 5A are provided on the top surfaces of the p-type column regions 4A of the edge termination region 40. The top surfaces of the p-type column regions 4A of the edge termination region 40 are in contact with the bottom surfaces of the p-type base regions 5A. Differences in planar shapes depicted in FIG. 2B and FIG. 2A are due to differences in positions of implantation regions where a later-described p-type impurity for forming the p-type column regions 4 is to be implanted. In the SJ-MOSFET 50 depicted in FIG. 2B, as depicted in later-described FIG. 9C, implantation regions 92 are formed in sections D2. In FIG. 2B, the p-type well regions 63, 63A are not provided, whereby a current path formed in the n-type drift layer 2 (the n-type column regions 3) has a region that is locally narrower. The current path becomes narrower due to a spreading of a depletion layer that spreads from pn junctions between the n-type column regions 3 and the p-type column regions 4, 4A due to the ON voltage occurring due to the flow of current. As a result, by omitting the p-type well regions 63, 63A, the ON resistance (resistance in an operating state) may be reduced as compared to FIG. 2A.

FIG. 2C is a cross-sectional view depicting another structure of the SJ-MOSFET 50 according to the embodiment. FIG. 2C differs from FIG. 2A in that contact holes 64D, 64E, 64F formed in the interlayer insulating film 9 include recesses 67A, 67B, 67C (grooves), and contact plugs 19 are embedded in the recesses 67A, 67B, 67C.

In the interlayer insulating film 9 covering the top surfaces of the gate electrodes 8 embedded in the trenches 18B of the active region 30, the recesses 67A are provided deeper than the top surface 100 in the y direction, between adjacent trenches 18B of the trenches 18B. The n⁺-type source regions 6 and the p⁺⁺-type contact regions 14 are in contact with (exposed at) sidewalls of the recesses 67A. The p⁺⁺-type contact regions 14 are in contact with (exposed at) bottoms of the recesses 67A. The recesses 67A are the contact holes 64D. Between the interlayer insulating film 9 and the gate electrodes 8, an insulating film (not depicted) is provided. Hereinafter, the insulating film (not depicted) provided between the interlayer insulating film 9 and the gate electrodes 8 is not further described.

Similarly, in the interlayer insulating film 9 covering the top surfaces of the gate electrodes 8 embedded in the trenches 18B, the recesses 67A are provided deeper than the top surface 100 in the y direction, between the trenches 18B at the border between the active region 30 and the edge termination region 40 and the trenches 18B respectively adjacent thereto in the active region 30. The n⁺-type source regions 6 and the p⁺⁺-type contact regions 14 are in contact with (exposed at) the sidewalls of the recesses 67A. The p⁺⁺-type contact regions 14 are in contact with (exposed at) the bottoms of the recesses 67A. The recesses 67A are the contact holes 64D.

In the interlayer insulating film 9, between a portion thereof covering the field plate 29 and portions thereof covering the top surfaces of the gate electrodes 8 embedded in the trenches 18B provided at the border between the active region 30 and the edge termination region 40, the recesses 67B are provided deeper than the top surface 100 in the y direction. The p⁺⁺-type contact regions 14A are in contact with (exposed at) sidewalls and bottoms of the recesses 67B. The recesses 67B are the contact holes 64E.

In the interlayer insulating film 9 covering the field oxide film 13, the field plate 29, and the channel stopper 62, the recess 67C is provided. The recess 67C penetrates through the field plate 29, whereby the surface of the field oxide film 13 is exposed. The field plate 29 is in contact with (exposed at) sidewalls of the recess 67C. Further, the recess 67C and the surface of the field oxide film 13 may have a recess (groove), and the field oxide film 13 may be in contact with (exposed at) the sidewalls of the recess 67C. The field oxide film 13 is in contact with (exposed at) a bottom of the recess 67C. The recess 67C is the contact hole 64F. An insulating film (not depicted) is provided between the interlayer insulating film 9 and the field plate 29 and between the interlayer insulating film 9 and the channel stopper 62. Hereinafter, the insulating film provided between the interlayer insulating film 9 and the field plate 29 and between the interlayer insulating film 9 and the channel stopper 62 is not further described.

The contact plugs 19, for example, are metal films containing highly embeddable tungsten (W) as a material. Further, the contact plugs 19 may be provided in the contact holes 64D, 64E, 64F via a barrier metal. The source electrode 10 is electrically connected to the n⁺-type source regions 6 and the p⁺⁺-type contact regions 14, via the contact plugs 19 in the contact holes 64D of the active region 30. Further, the source electrode 10 extends to a portion of the edge termination region 40 and is electrically connected to the p⁺⁺-type contact regions 14A via the contact plugs 19 in the contact holes 64E of the edge termination region 40.

The metal gate runner 61 is electrically connected to the field plate 29 via the contact plug 19 in the contact hole 64F. The source electrode 10 and the metal gate runner 61 are electrically insulated.

FIG. 2C, similarly to FIG. 2A, depicts an instance in which the parallel pn region 20B closer to the outer periphery of the SJ-MOSFET 50 than are the p-type column regions 4A of the edge termination region 40 is not provided. In FIG. 2C, the parallel pn region 20B that is closer to the outer periphery of the SJ-MOSFET 50 than are the p-type column regions 4A of the edge termination region 40 may be provided as depicted in FIG. 1.

FIG. 2D is a cross-sectional view depicting another structure of the SJ-MOSFET 50 according to the embodiment. FIG. 2D differs from FIG. 1 in that the p-type well regions 63, 63A that are in contact with the top surfaces of the p-type column regions 4, 4A are in contact with the sidewalls of the trenches 18B. In FIG. 2D, the p-type well regions 63 of the active region 30 extend in the x direction depicted in FIG. 2D and are in contact with the sidewalls of the trenches 18B; and the p-type well regions 63A of the edge termination region 40 extend in the x direction depicted in FIG. 2D and are in contact with the trenches 18B provided at the border of the edge termination region 40.

As a result, the p-type well regions 63, 63A and the p-type base regions 5, 5A are in contact with the sidewalls of the trenches 18B. Therefore, it becomes easier to prevent failures due to channel defects such as short-channels and defects of the p-type column regions 4, 4A. Furthermore, a 2-step concentration gradient due to the p-type well regions 63, 63A and the p-type base regions 5, 5A mitigates electric field near a channel junction and it becomes easy to secure a sufficient channel length.

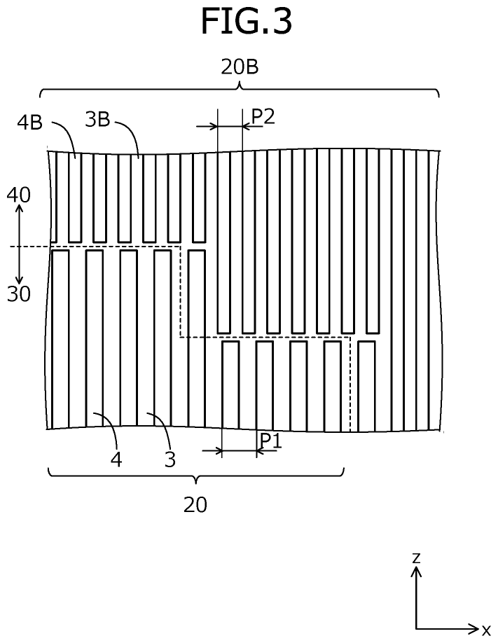

FIG. 3 is a plan view depicting the structure of the SJ-MOSFET according to the embodiment and is a plan view of along cutting line A-A′ in FIG. 1. As depicted in FIG. 3, a repetition pitch P2 of the parallel pn region 20B of the edge termination region 40 is narrower than a repetition pitch P1 of the parallel pn region 20 of the active region 30.

The repetition pitch P1 of the parallel pn region 20, in the x direction depicted in FIG. 3, represents a sum of the width of one of the n-type column regions 3 and the width of one of the p-type column regions 4 adjacent thereto. Further, the repetition pitch P2 of the parallel pn region 20B, in the x direction depicted in FIG. 3, represents a sum of the width of one of the n-type column regions 3B and the width of one of the p-type column regions 4B adjacent thereto. To ensure avalanche tolerance by the SJ-MOSFET 50 (superjunction semiconductor device), the breakdown voltage of the edge termination region 40 has to be set higher than the breakdown voltage of the active region 30. Therefore, the width of the n-type column regions 3B and the width of the p-type column regions 4B of the edge termination region 40 suffice to be narrower than the width of the n-type column regions 3 and the width of the p-type column regions 4 of the active region 30. As a result, in the edge termination region 40, spreading of a depletion layer is facilitated and the breakdown voltage of the edge termination region 40 may be set higher than the breakdown voltage of the active region 30.

As depicted in FIG. 3, a planar shape of the n-type column regions 3 and the p-type column regions 4 of the active region 30 in a plan view thereof, for example, may be a stripe shape structure having a length dimension parallel to the z direction. Further, the n-type column regions 3B and the p-type column regions 4B in the edge termination region 40 may also have a strip shape structure having a length dimension parallel to the z direction. Moreover, while not depicted, a planar shape of the trenches 18B in a plan view thereof may be a stripe shape having a length dimension parallel to the z direction.

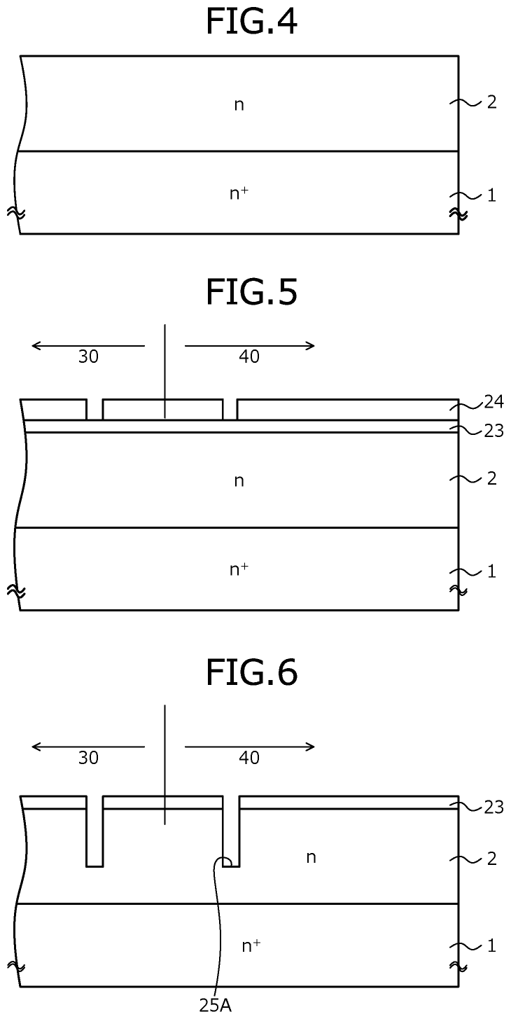

Next, a method of manufacturing the superjunction semiconductor device according to the embodiment is described. FIGS. 4, 5, 6, 7, 8, 9A, 9B, 9C, 10A, 10B, 10C, 11, 12, 13, 14, 15, 16, 17, 18, 19, 20, and 21 are cross-sectional views depicting states of the SJ-MOSFET according to the embodiment during manufacture by a first method of manufacturing. First, the n⁺-type semiconductor substrate 1 containing silicon and forming an n⁺-type drain layer is prepared.

Next, on a front surface of the n⁺-type semiconductor substrate 1, the n-type drift layer 2 having an impurity concentration lower than the impurity concentration of the n⁺-type semiconductor substrate 1 is epitaxially grown. At this time, an n-type impurity may be doped during the epitaxial growth so that the impurity concentration of the n-type drift layer 2 is in a range from 1.0×10¹⁶/cm³ to 3.0×10¹⁷/cm³. For example, when the superjunction semiconductor device is formed having a breakdown voltage of 40V, the impurity concentration of the n-type drift layer 2 may be set to be at most 1.0×10¹⁷/cm³. Further, for example, when the superjunction semiconductor device is formed having a breakdown voltage of 100V, the impurity concentration of the n-type drift layer 2 may be set to be 5.0×10¹⁶/cm³. The impurity concentration of the n-type drift layer 2 is constant in the depth direction. Here, the depth direction is a direction from the surface of the n-type drift layer 2 toward the n⁺-type semiconductor substrate 1. The state up to here is depicted in FIG. 4.

Next, an oxide film 23 is formed on the surface of the n-type drift layer 2. Next, on a surface of the oxide film 23, a resist mask 24 having predetermined openings at positions where the p-type column regions 4 are to be formed is formed by a photolithographic technique. The state up to here is depicted in FIG. 5.

Next, openings that expose the n-type drift layer 2 are formed in the oxide film 23 by drying etching, using the resist mask 24 as a mask. Next, the resist mask 24 is removed, the oxide film 23 having the openings is used as a mask and, for example, anisotropic dry etching is performed, whereby p-type column trenches (first trenches) 25A are formed in the n-type drift layer 2. The state up to here is depicted in FIG. 6.

Next, isotropic etching and sacrificial oxidation are performed with the oxide film 23 attached as is. By this process, damage of the p-type column trenches 25A is removed and bottoms of the p-type column trenches 25A become curved. As for a sequence in which the isotropic etching and the sacrificial oxidation are performed, either may be performed first. Further, the isotropic etching or the sacrificial oxidation alone may be performed.

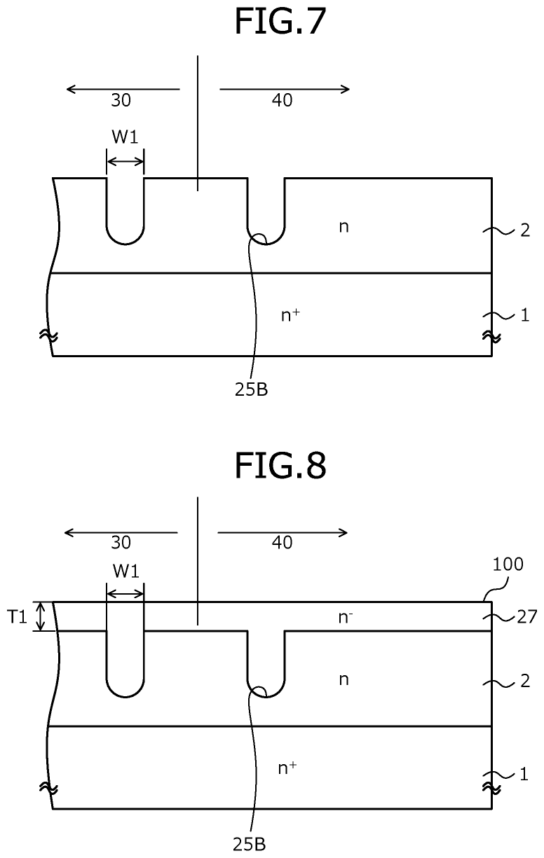

Thereafter, the oxide film 23 is removed. The oxide film 23 may be removed concurrently with a sacrificial oxide film (not depicted). After removal of the oxide film 23, p-type column trenches 25B are formed having a width W1. The state up to here is depicted in FIG. 7.

Next, the n⁻-type epitaxial layer 27 having an impurity concentration lower than the impurity concentration of the n-type drift layer 2 is epitaxially grown so as to cover the surface of the n-type drift layer 2 and be embedded in the p-type column trenches 25B. At this time, an n-type impurity may be doped during epitaxial growth so that the impurity concentration of the n⁻-type epitaxial layer 27 is in a range from 1.0×10¹⁵/cm³ to 5.0×10¹⁶/cm³. For example, when the superjunction semiconductor device is formed having a breakdown voltage of 40V, the impurity concentration of the n⁻-type epitaxial layer 27 may be set to be 2.0×10¹⁶/cm³. Further, when the superjunction semiconductor device is formed having a breakdown voltage of 100V, the impurity concentration of the n⁻-type epitaxial layer 27 may be set to be 1.0×10¹⁶/cm³.

A relationship between the impurity concentration of the n-type drift layer 2 and the impurity concentration of the n⁻-type epitaxial layer 27 is a>b, where the impurity concentration of the n-type drift layer 2 is a[/cm³] and the impurity concentration of the n⁻-type epitaxial layer 27 is b[/cm³]. The impurity concentration 2a[/cm³] of the n-type drift layer and the impurity concentration b[/cm³] of the n⁻-type epitaxial layer 27 satisfy a relational expression 2≤a/b≤10.

A thickness of flat portions of the n⁻-type epitaxial layer 27 is assumed to be a thickness T1. The flat portions of the n⁻-type epitaxial layer 27 are portions where the n⁻-type epitaxial layer 27 is formed on the surface of the n-type drift layer 2 free of the p-type column trenches 25B. The surface of the flat portions of the n⁻-type epitaxial layer 27 is assumed as the top surface 100.

When the n⁻-type epitaxial layer 27 is formed, the thickness T1 is assumed to be a value greater than ½ of a width W1 of the p-type column trenches 25B (T1>W1/2). By setting the thickness T1 to be greater than ½ of the width W1 of the p-type column trenches 25B, a process of planarizing the top surface 100 (surface) of the n⁻-type epitaxial layer 27 using CMP equipment, etc. needs not be performed. The state up to here is depicted in FIG. 8.

FIGS. 9A, 9B, and 9C are cross-sectional views of states when an ion implantation 22 is performed using an ion implantation mask 21 to form implanted regions under different conditions. First, on the surface (the top surface 100) of the n⁻-type epitaxial layer 27, the ion implantation mask 21 having predetermined openings is formed by a photolithographic technique using, for example, a photoresist. The openings of the ion implantation mask 21 are formed at upper portions of the p-type column trenches 25B. The ion implantation 22 of a p-type impurity is performed using the ion implantation mask 21 as a mask. The p-type impurity is, for example, boron (B) or aluminum (Al), etc. The ion implantation 22 may be performed one time or multiple times at different implantation depths. When the ion implantation 22 is performed multiple times at different depths, a sequence of the ion implantation 22 may be variously changed. Here, the depth indicates a direction from the top surface 100 (surface) of the n⁻-type epitaxial layer 27 toward the front surface of the n+-type semiconductor substrate 1. The implantation depth is the depth of implantation of an impurity from the top surface 100 (surface) of the n⁻-type epitaxial layer 27 (position of a peak of the impurity concentration distribution).

Further, later-described implanted regions 90, 91-1, 91-2, 92 formed by the ion implantation 22 indicate regions in which an impurity is implanted from the top surface 100 (position of a peak of the impurity concentration distribution). Therefore, an implantation depth indicates a depth from the top surface 100 (surface) of the n⁻-type epitaxial layer 27 to the implanted regions 90, 91-1, 91-2, 92 formed in the n⁻-type epitaxial layer 27.

Further, between the surface (the top surface 100) of the n⁻-type epitaxial layer 27 and the surface of the n-type drift layer 2 (the thickness T1 of the flat portion of the n⁻-type epitaxial layer 27) is regarded as a section D1 and between the surface of the n-type drift layer 2 (surface of the semiconductor base) and the bottom of each of the p-type column trenches 25B is regarded as the sections D2.

In FIG. 9A, the ion implantation 22 is performed one time, thereby forming the implanted regions 90. The implanted regions 90 are formed in the section D1. For example, in an instance in which the section D1 is 0.8 μm and the sections D2 are 1.0 μm, the implantation depth of the implanted regions 90 is 0.4 μm. The section D1 suffices to be in a range from 0.5 μm to 1.0 μm. The implantation depth of the implanted regions 90 suffices to be in a range from 0.2 μm to 1.0 μm. The sections D2 suffice to be in a range from 0.5 μm to 2.0 μm. The implanted regions 90 may be formed at a border between the section D1 and the sections D2.

In FIG. 9B, the ion implantation 22 is performed two times, whereby the implanted regions 91-1, 91-2 are formed. The implanted regions 91-1 are formed in the section D1 and the implanted regions 91-2 are formed in the sections D2. For example, in an instance in which the section D1 is 0.8 μm and the sections D2 are 1.0 μm, the implantation depth of the implanted regions 91-1 is set to be 0.4 μm, and the implantation depth of the implanted regions 91-2 is set to be 1.6 μm. The section D1 suffices to be in a range from 0.5 μm to 1.5 μm. The implantation depth of the implanted regions 91-1 and the implantation depth of the implanted regions 91-2 suffice to be in a range from 0.2 μm to 2.0 μm. The sections D2 suffice to be in a range from 1.0 μm to 4.0 μm. The implanted regions 91-1 or the implanted regions 91-2 may be formed at the border between the section D1 and the sections D2. As for a sequence in which the implanted regions 91-1 and the implanted regions 91-2 are formed, either may be formed first.

In FIG. 9C, the ion implantation 22 is performed one time, whereby the implantation regions 92 are formed. The implantation regions 92 are formed in the sections D2. For example, in an instance in which the section D1 is 0.8 μm and the sections D2 are 1.0 μm, the implantation depth of the implantation regions 92 is set to be 1.2 μm. The section D1 suffices to be in a range from 0.5 μm to 1.5 μm. The implantation depth of the implantation regions 92 suffices to be in a range from 0.4 μm to 2.0 μm. The implantation regions 92 may be formed at the border between the section D1 and the sections D2.

FIGS. 9A, 9B, and 9C depict representative examples of the implantation depth of p-type impurity and the number of implantations of the ion implantation 22 and the implantation depth and the number of implantations, etc. of the implanted regions may be variously changed.

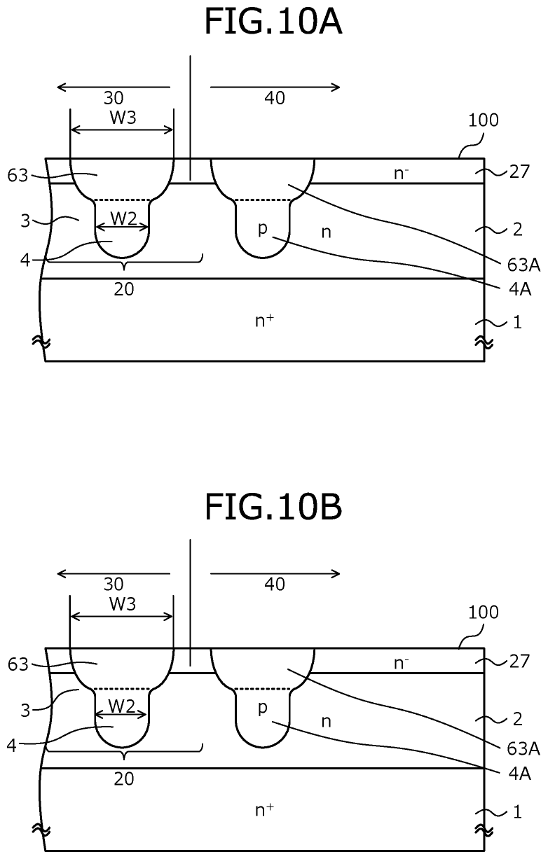

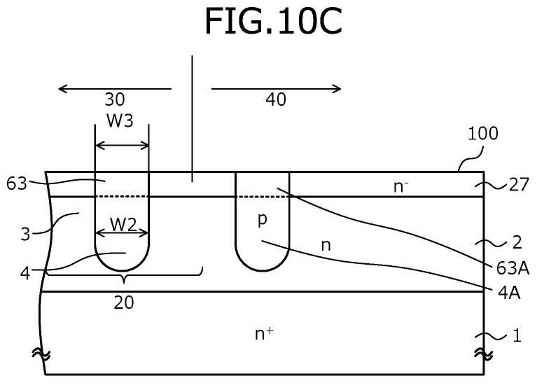

FIG. 10A is a cross-sectional view in which the ion implantation mask 21 is removed after the ion implantation 22 in FIG. 9A and the p-type impurity is diffused by a heat treatment. The n⁻-type epitaxial layer 27 has an impurity concentration lower than the impurity concentration of the n-type drift layer 2 and therefore, by the ion implantation 22 of the p-type impurity and the heat treatment thereafter, spreading of the p-type impurity in the n⁻-type epitaxial layer 27 from the implanted regions 90 is facilitated. Therefore, in the n-type drift layer 2, the p-type well regions 63 are formed having a width W3 at the top surface 100 of the n⁻-type epitaxial layer 27 wider than a width W2 of the p-type column regions 4.

Between adjacent p-type column regions 4 of the p-type column regions 4 are the n-type column regions 3, and the parallel pn region 20 is formed in the n-type drift layer 2. Further, the p-type column regions 4A and the p-type well regions 63A of the edge termination region 40 are also similarly formed by the same processes.

The p-type impurity concentration in FIG. 10A is highest at the implanted regions 90 depicted in FIG. 9A and the impurity concentration decreases with increasing distance from the implanted regions 90 in the depth direction. Here, the depth direction is a direction from the surface of the n⁻-type epitaxial layer 27 toward the n⁺-type semiconductor substrate 1.

FIG. 10B is a cross-sectional view in which the ion implantation mask 21 is removed after the ion implantation 22 in FIG. 9B and the p-type impurity is diffused by a heat treatment. The n⁻-type epitaxial layer 27 has an impurity concentration lower than the impurity concentration of the n-type drift layer 2 and therefore, by the ion implantation 22 of the p-type impurity and the heat treatment thereafter, spreading of the p-type impurity in the n⁻-type epitaxial layer 27 from the implanted regions 91-1 and the implanted regions 91-2 is facilitated. Therefore, in the n-type drift layer 2, the p-type well regions 63 are formed having the width W3 at the top surface 100 of the n⁻-type epitaxial layer 27 wider than the width W2 of the p-type column regions 4.

Between adjacent p-type column regions 4 of the p-type column regions 4 are the n-type column regions 3, and the parallel pn region 20 is formed in the n-type drift layer 2. Further, the p-type column regions 4A and the p-type well regions 63A of the edge termination region 40 are also similarly formed by the same processes.

The p-type impurity concentration in FIG. 10B is highest at the implanted regions 91-1 and the implanted regions 91-2 and decreases with increasing distance from the implanted regions 91-1 and the implanted regions 91-2 in the depth direction. At portions where diffusion of the p-type impurity of the implanted regions 91-1 and diffusion of the implanted regions 91-2 overlap with one another, the p-type impurity is abundant and even with increasing distance from the implanted regions 91-1 and the implanted regions 91-2 in the depth direction, the concentration is high. Here, the depth direction is a direction from the surface of the n⁻-type epitaxial layer 27 toward the n⁺-type semiconductor substrate 1.

FIG. 10C is cross-sectional view in which the ion implantation mask 21 is removed after the ion implantation 22 in FIG. 9C and the p-type impurity is diffused by a heat treatment. The n⁻-type epitaxial layer 27 has an impurity concentration lower than the impurity concentration of the n-type drift layer 2 and therefore, by the ion implantation 22 of the p-type impurity and the heat treatment thereafter, spreading of the p-type impurity in the n⁻-type epitaxial layer 27 from the implantation regions 92 is facilitated.

The implantation regions 92 depicted in FIG. 9C are formed in the sections D2, apart from the top surface 100 of the n⁻-type epitaxial layer 27. Therefore, near the top surface 100 of the n⁻-type epitaxial layer 27, the p-type impurity of the implantation regions 92 do not easily diffuse in a direction orthogonal to the depth direction (direction parallel to the widths W2, W3). As a result, the width W2 of the p-type column regions 4 and the width W3 of the p-type well regions 63 at the top surface 100 of the n⁻-type epitaxial layer 27 may be formed to be equal to each other.

Between adjacent p-type column regions 4 of the p-type column regions 4 are the n-type column regions 3, and the parallel pn region 20 is formed in the n-type drift layer 2. Further, the p-type column regions 4A and the p-type well regions 63A of the edge termination region 40 are also similarly formed by the same processes. The p-type impurity concentration in FIG. 10C is highest at the implantation regions 92 depicted in FIG. 9C and the impurity concentration decreases with increasing distance from the implantation regions 92. Here, the depth direction is a direction from the surface of the n⁻-type epitaxial layer 27 toward the n⁺-type semiconductor substrate 1.

In FIGS. 10A and 10B, a cross-sectional shape of the p-type well regions are similar, however, in FIG. 10C, the cross-sectional shape differs from that in FIGS. 10A and 10B. This is due to the position of the implanted regions formed by the ion implantation 22 differing. Manufacturing processes hereinafter are described based on the state depicted in FIG. 10A. Here, the depth direction is a direction from the surface (the top surface 100) of the n⁻-type epitaxial layer 27 toward the n⁺-type semiconductor substrate 1. Further, “shallow” and “deep” indicate a depth in the depth direction.

Further, while an instance in which a photoresist is used as the ion implantation mask 21 is described, for example, an oxide film may be used. In an instance in which an oxide film is used, openings are formed in the oxide film by a photolithographic technique and an etching technique. In an instance in which an oxide film is used for the ion implantation mask 21, a heat treatment for diffusing the implanted impurity may be performed with the oxide film attached as is.

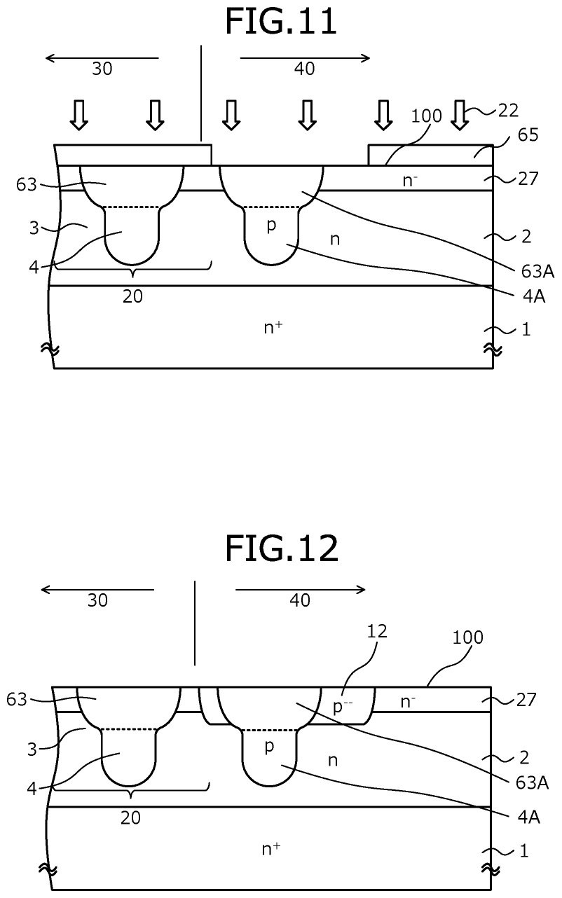

On the surface (the top surface 100) of the n⁻-type epitaxial layer 27, an ion implantation mask 65 having an opening for forming the p⁻⁻-type RESURF region 12 is formed by a photolithographic technique. For example, a photoresist is used for the ion implantation mask 65. An ion implantation of a p-type impurity is performed using the ion implantation mask 65 as a mask. The p-type impurity is, for example, boron (B) or aluminum (Al), etc. The state up to here is depicted in FIG. 11.

Next, the ion implantation mask 65 is removed and thereafter, the heat treatment for diffusing the implanted p-type impurity is performed, whereby the p⁻-type RESURF region 12 is formed in a surface layer of the n⁻-type epitaxial layer 27. The p⁻⁻-type RESURF region 12 has an impurity concentration lower than the impurity concentration of the p-type well regions 63A and therefore, the p⁻-type RESURF region 12 is not formed in the p-type well regions 63A. The bottom surface of the p⁻⁻-type RESURF region 12 is formed deeper than is a border between the n⁻-type epitaxial layer 27 and the n-type drift layer 2. Further, the bottom surface of the p⁻⁻-type RESURF region 12 may be shallower than borders (dotted line) between the p-type column regions 4A and the p-type well regions 63A. The state up to here is depicted in FIG. 12.

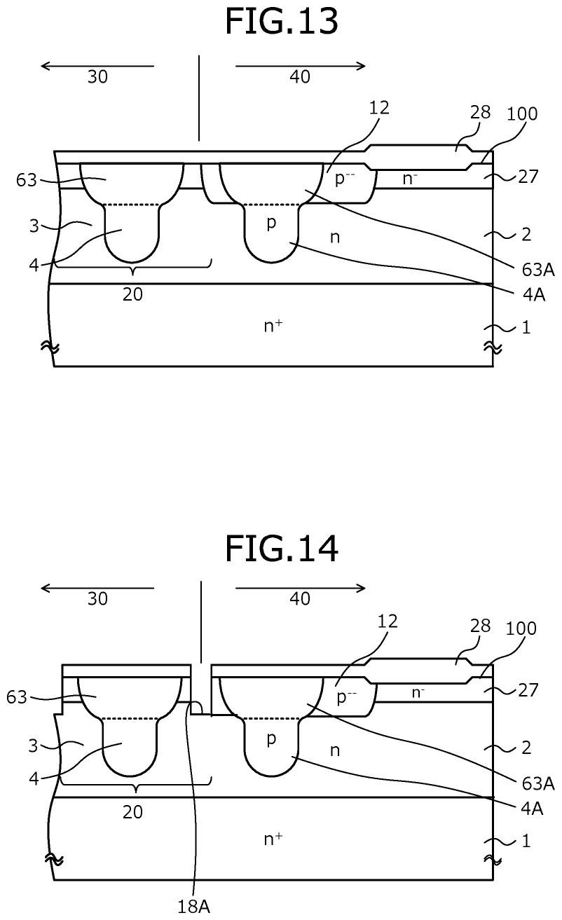

Next, on the top surface 100, an oxide film 28 is formed. The oxide film 28 may be, for example, a LOCOS film. The oxide film 28 is formed so that a portion thereof in the active region 30 has a thickness that is less than a thickness of a thick portion thereof closer to the outer periphery of the edge termination region 40. The oxide film 28 is formed so that the thick portion where the thickness thereof is thick is at the top surface of the n⁻-type epitaxial layer 27 and a bottom surface of the thick portion of the oxide film 28 is formed at a position deeper than is the top surface 100. In the thick portion of the oxide film 28, an end thereof facing the active region 30 is formed so that continuously from the end to a portion of the bottom surface thereof is covered by the p⁻⁻-type RESURF region 12 therebelow. Further, the other end of the thick portion of the oxide film 28 is formed so that continuously from the other end to a portion of the bottom surface thereof is covered by the n⁻-type epitaxial layer 27 therebelow. The state up to here is depicted in FIG. 13.

Next, on a surface of the oxide film 28, a resist mask (not depicted) having predetermined openings is formed by a photolithographic technique. Next, openings are formed in the oxide film 28 by dry etching using the resist mask as a mask. Next, the resist mask is removed and the trenches 18A that penetrate the n⁻-type epitaxial layer 27 from the top surface 100 of the n⁻-type epitaxial layer 27 and reach the n-type drift layer 2 are formed by anisotropic dry etching using the oxide film 28 as a mask. The state up to here is depicted in FIG. 14.

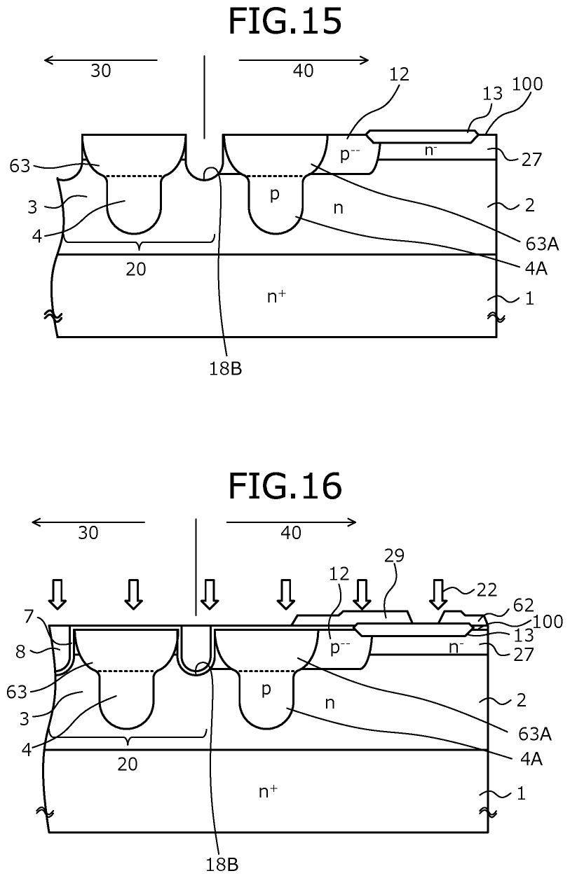

Next, with the oxide film 28 attached as is, isotropic etching and sacrificial oxidation are performed. By these processes, damage of the trenches 18A is removed and bottoms of the trenches 18A become curved. As for a sequence in which the isotropic etching and the sacrificial oxidation are performed, either may be performed first. Further, the isotropic etching or the sacrificial oxidation alone may be performed. Thereafter, a portion of the oxide film 28 where the thickness thereof is thin and used for forming the trenches 18A is removed. At this time, the sacrificial oxide film may be removed concurrently with the portion of the oxide film 28 where the thickness thereof is thin. The trenches 18A after the oxide film 28 is removed become the trenches 18B. The oxide film 28 has the portion where the thickness thereof is thin and the portion where the thickness thereof is thick in the edge termination region 40 and therefore, an entire area of the surface of the portion thereof where the thickness thereof is thin is etched and removed, leaving the thick portion of the oxide film 28 where the thickness thereof is thick in the edge termination region 40. The sacrificial oxide film (not depicted) may be removed together with the portion of the oxide film 28 where the thickness thereof is thin. Further, the oxide film 28 may be removed by a photolithographic technique and an etching technique, to thereby leave the oxide film 28 in the edge termination region 40. The oxide film 28 left in the edge termination region 40 (the portion of the oxide film 28 where the thickness thereof is thick) becomes the field oxide film 13. The state up to here is depicted in FIG. 15.

Next, the gate insulating films 7 are formed along the surfaces (the top surface 100) of the n⁻-type epitaxial layer 27, the p⁻⁻-type RESURF region 12, and the p-type well regions 63, 63A, and along inner walls of the trenches 18B. The gate insulating films 7 may be formed by thermal oxidation of a temperature of about 1000 degrees C. under an oxygen atmosphere. Further, the gate insulating films 7 may be formed by a deposition method by a chemical reaction such as that for a high temperature oxide (HTO).

Next, on the gate insulating films 7, for example, a polycrystalline silicon layer doped with phosphorus atoms is provided. The polycrystalline silicon layer is formed so as to be embedded in the trenches 18B. The polycrystalline silicon layer is patterned by a photolithographic technique and an etching technique, thereby forming the gate electrodes 8 in the trenches 18B via the gate insulating films 7.

Further, the polycrystalline silicon layer formed in the edge termination region 40 may be selectively left as the field plate 29 and the channel stopper 62.

The field plate 29 is formed continuously on the top surfaces of the gate insulating films 7 (the insulating film 66A) formed on the p⁻⁻-type RESURF region 12, the p-type well regions 63A, and the p-type base regions 5A (not depicted) (the top surface 100), and the top surface of a portion of the field oxide film 13 closer to the active region 30 than to the outer periphery of the edge termination region 40. The field plate 29 is electrically connected to the gate electrodes 8 and has a function of gate wiring.

The channel stopper 62 is formed continuously on the top surface of an outer peripheral side of the field oxide film 13 and the top surfaces of the gate insulating films 7 (the insulating film 66B) formed on the n⁻-type epitaxial layer 27 (the top surface 100). The field plate 29 and the channel stopper 62 are separate from each other on the field oxide film 13.

Next, from the top surface 100 of the n⁻-type epitaxial layer 27 (surfaces of the p-type well regions 63, 63A, and the n⁻-type epitaxial layer 27), the ion implantation 22 of a p-type impurity for forming the p-type base regions 5, 5A is performed. The p-type impurity is, for example, boron (B) or aluminum (Al), etc. At this time, on the n⁻-type epitaxial layer 27 in the edge termination region 40, the field plate 29, the channel stopper 62, and the field oxide film 13 function as a mask. Therefore, the p-type impurity is not implanted in the n⁻-type epitaxial layer 27. Further, the gate electrodes 8 also function as a mask. The state up to here is depicted in FIG. 16. Next, removal of the gate insulating films 7 formed on the top surface 100 is performed. The removal of the gate insulating films 7 needs not be performed when the thickness of the gate insulating films 7 is a thickness that does not obstruct the ion implantation for forming the n⁺-type source regions 6, as described hereinafter, for example, a thickness that is at most 500 Å.

Next, the p-type impurity is diffused by a heat treatment, whereby the p-type base regions 5, 5A are formed in surface layers of the n⁻-type epitaxial layer 27, the p-type well regions 63, 63A, and the p⁻⁻-type RESURF region 12. By this heat treatment, an insulating film 66C is formed so as to cover the top surfaces of the field plate 29, the channel stopper 62 and the gate electrodes 8 formed by the polycrystalline silicon layer that is formed so as to be embedded in the trenches 18B.

The p-type base regions 5 and the p-type well regions 63 overlap one another and the bottom surfaces of the p-type base regions 5 are formed shallower than the bottom surfaces of the p-type well regions 63. The p-type base regions 5A and the p-type well regions 63A overlap one another and the bottom surfaces of the p-type base regions 5A are formed shallower than the bottom surfaces of the p-type well regions 63A.

The impurity concentration of the p-type base regions 5 and the impurity concentration of the p-type base regions 5A may be equal to each other. The impurity concentration of the p-type well regions 63 and the impurity concentration of the p-type well regions 63A may be equal to each other. The impurity concentration of the p-type base regions 5 is higher than the impurity concentration of the p-type well regions 63. Further, the impurity concentration of the p-type base regions 5A is higher than the impurity concentration of the p-type well regions 63A. The p-type base regions 5, 5A are formed to be in contact with the sidewalls of the trenches 18B.

In the edge termination region 40, the oxide film 28, the field plate 29, and the channel stopper 62 function as a mask and therefore, boron (B) is not implanted in upper portions of the n⁻-type epitaxial layer 27 or the p⁻⁻-type RESURF region 12 covered by the oxide film 28, the field plate 29, or the channel stopper 62. As a result, even when the heat treatment for diffusing the p-type impurity to form the p-type base regions 5, 5A is performed, the p-type impurity that forms the p-type base regions 5, 5A does not diffuse into the n⁻-type epitaxial layer 27 or the p⁻⁻-type RESURF region 12. Therefore, the n⁻-type epitaxial layer 27 and the p⁻⁻-type RESURF region 12 remain in the edge termination region 40.

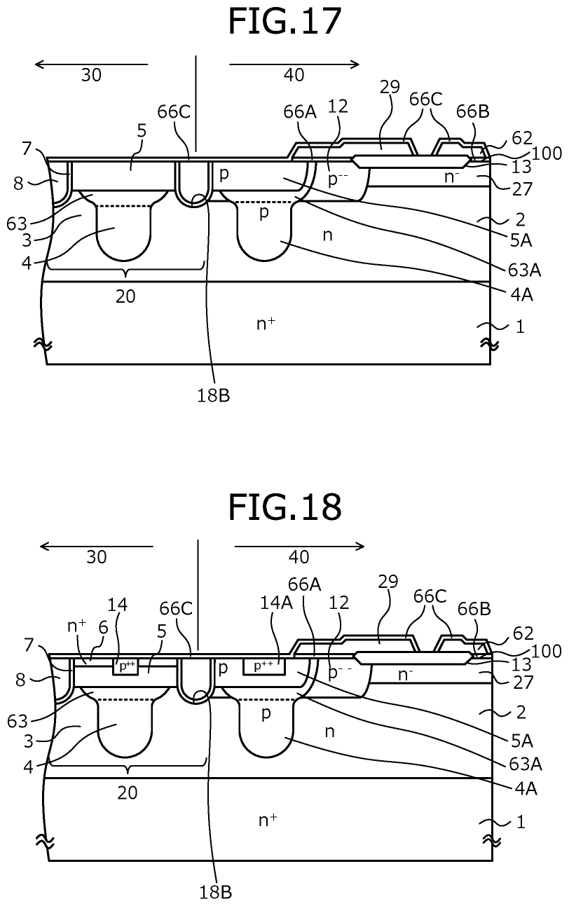

In this manner, in the first method of manufacturing, the p-type base regions 5 where the channels are formed are formed after the formation of the trenches 18B. The state up to here is depicted in FIG. 17.

Next, on the surfaces of the p-type base regions 5, for example, a mask having predetermined openings (not depicted) is formed by a photolithographic technique using a resist. An ion implantation of an n-type impurity is performed using the resist mask as a mask. By this ion implantation, the n-type impurity is implanted at places where the n⁺-type source regions 6 are to be formed in surface layers of the p-type base regions 5. The implanted n-type impurity is arsenic (As), phosphorus (P), etc.

Next, the ion implantation mask used for forming the n⁺-type source regions 6 is removed. Further, on the surfaces of the p-type base regions 5, for example, a mask having predetermined openings may be formed by a photolithographic technique using a resist and a p-type impurity may be implanted forming, in surface layers of the p-type base regions 5, the p⁺⁺-type contact regions 14 in contact with the n⁺-type source regions 6. Further, in surface layers of the p-type base regions 5A as well, a p-type impurity may be implanted forming the p⁺⁺-type contact regions 14A. The n⁺-type source regions 6 are not formed in surface layers of the p-type base regions 5A in the edge termination region 40.

Next, to form the n⁺-type source regions 6 and the p⁺⁺-type contact regions 14, 14A, a heat treatment that activates the implanted impurities is performed. Here, a difference between the heat treatment for activation and the heat treatment after ion implantation (the heat treatment that diffuses the implanted impurities) is described. In the semiconductor base, for example, the n-type drift layer 2, in which ion implantation is performed, damage occurs due to the ion implantation and defects are generated. Due to the defects, not all of the ion-implanted impurities are in an active state as charge. The heat treatment for activation indicates a heat treatment that causes recovery of the defects generated by ion implantation and makes the amount of charge (resistance) commensurate with the impurity amount implanted. The heat treatment after ion implantation (heat treatment that diffuses the ion-implanted impurities) indicates a heat treatment that causes recovery of the defects generated by ion implantation, makes the amount of charge (resistance) commensurate with the impurity amount implanted, and causes the impurities to diffuse to an arbitrary position in the semiconductor base, for example, the n-type drift layer 2, etc. Therefore, the heat treatment for activation has a thermal history smaller than a thermal history of the heat treatment after ion implantation (heat treatment that diffuses the ion-implanted impurities). The thermal history being small, for example, indicates that the heat treatment temperature is low, or the heat treatment time is short, or the heat treatment temperature is low and the heat treatment time is short. As for a sequence in which the ion implantations for forming the n⁺-type source regions 6 and the p⁺⁺-type contact regions 14, 14A are performed, either may be performed first. The state up to here is depicted in FIG. 18.

Next, the interlayer insulating film 9 is formed in an entire area of an upper portion of the surface (the top surface 100) of the n⁻-type epitaxial layer 27. The interlayer insulating film 9 is formed so as to cover, via the insulating film 66C, for example, upper portions of the gate insulating films 7, the gate electrodes 8, the n⁺-type source regions 6, the p⁺⁺-type contact regions 14, the p-type base regions 5A, the p⁺⁺-type contact regions 14A, the field oxide film 13, the field plate 29, and the channel stopper 62. The interlayer insulating film 9 contains, for example, a boron phosphorus silicate glass (BPSG), a phosphorus silicate glass (PSG), etc. Further, the interlayer insulating film 9 may be formed as a layered film having, for example, a high temperature oxide (HTO), a non-doped silicate glass (NSG), or a tetraethyl orthosilicate (TEOS) film beneath the BPSG (between the BPSG and the gate electrodes 8). The thickness of the interlayer insulating film 9 suffices to be about 1 μm.

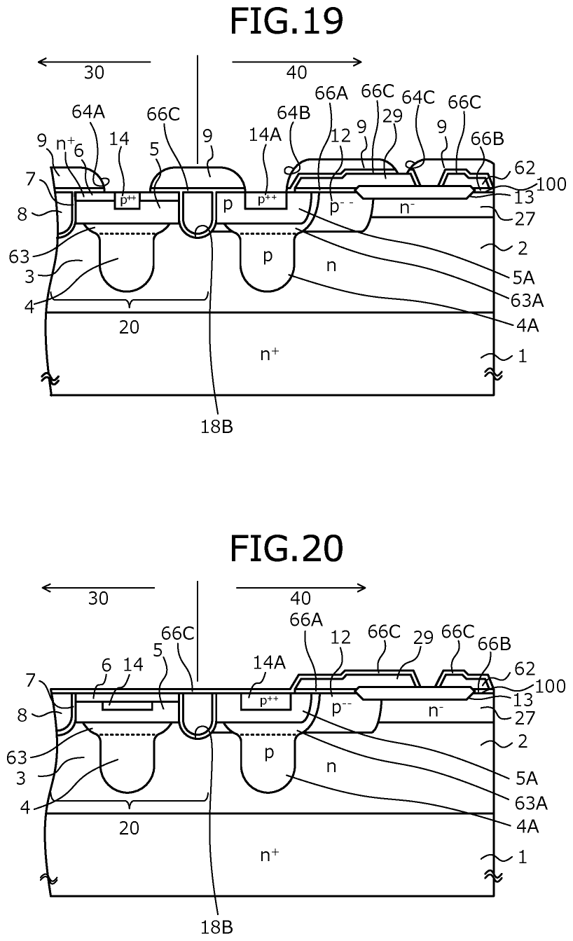

Next, the interlayer insulating film 9 and the insulating film 66C are patterned by a photolithographic technique and an etching technique. In the active region 30, the contact holes 64A that expose the surfaces of the n⁺-type source regions 6 and the p⁺⁺-type contact regions 14 are formed (borders between the interlayer insulating film 9 covering the upper portions of the gate electrodes 8 and the gate insulating films 7 formed along the inner walls of the trenches 18B are not depicted). Further, in the edge termination region 40, the contact holes 64B that expose the surfaces of the p⁺⁺-type contact regions 14A are formed. Further, in the edge termination region 40, the contact hole 64C that exposes the surface of the field plate 29 is formed. Thereafter, a heat treatment (reflow) is performed, thereby planarizing the interlayer insulating film 9. The state up to here is depicted in FIG. 19.

Next, by sputtering, aluminum or an alloy having aluminum as a main component (Al—Si, Al—Cu, Al—Si—Cu), etc. is embedded in the contact holes 64A, 64B, 64C and is further deposited so as to be continuous on the top surface of the interlayer insulating film 9. Before the metal film is deposited, by sputtering, a barrier metal (not depicted) may be formed by a titanium film (Ti), a titanium nitride film (TiN), or a layered film of these (for example, Ti/TiN, etc.) so as to be continuous along inner walls of the contact holes 64A, 64B, 64C and on the top surface of the interlayer insulating film 9. Thereafter, the metal film and the barrier metal (not depicted) are patterned by a photolithographic technique and an etching technique, whereby the source electrode 10, the metal gate runner 61, and a gate electrode pad (not depicted) are formed. Configuration may be such that the barrier metal is formed in only the contact holes 64A, 64B, 64C.

The source electrode 10, in the active region 30, is electrically connected to the n⁺-type source regions 6 and the p⁺⁺-type contact regions 14 whose surfaces are exposed by the contact holes 64A. Further, the source electrode 10, in the edge termination region 40, is electrically connected to the p⁺⁺-type contact regions 14A whose surfaces are exposed by the contact holes 64B. Further, the metal gate runner 61 is electrically connected to the field plate 29 and the gate electrodes 8 whose surfaces are exposed by the contact hole 64C. The gate electrode pad (not depicted) is electrically connected to the metal gate runner 61 and the gate electrodes 8. In the contact holes 64A, 64B, 64C, tungsten plugs, etc. may be embedded via the barrier metal.

Next, by sputtering, the back electrode 11 is formed on a back surface of the n⁺-type semiconductor substrate 1 (the back surface of the semiconductor base). The back electrode 11 may be formed by, for example, a metal film containing nickel (Ni), titanium (Ti), gold (Au), silver (Ag), aluminum (Al), or an alloy containing aluminum as a main component (Al—Si, Al—Cu, Al—Si—Cu), etc. Further, a layered film of these (for example, Ti/Ni/Au, Al/Ti/Ni/Au, etc.) may be deposited as the back electrode 11. After the back electrode 11 is deposited, a heat treatment is performed, thereby forming an ohmic contact between the n⁺-type semiconductor substrate 1 and the back electrode 11. Thus, the SJ-MOSFET 50 depicted in FIG. 2A is completed.

In this manner, the p-type column trenches 25B are formed in regions that are to become the p-type column regions 4, 4A, and the n⁻-type epitaxial layer 27 that has an impurity concentration lower than the impurity concentration of the n-type drift layer 2 that forms the n-type column regions 3 is formed so as to be embedded in p-type column trenches 25.

Furthermore, ion implantation of a p-type impurity from the surface (the top surface 100) of the n⁻-type epitaxial layer 27 and a heat treatment for diffusing the implanted impurity are performed, thereby forming the p-type column regions 4, 4A, and the p-type well regions 63, 63A. As a result, the p-type column regions 4 may be formed without depositing a p-type epitaxial layer and therefore, a process of removing the p-type epitaxial layer in the edge termination region 40 becomes unnecessary. Further, a process of using CMP equipment, etc. to planarize the surface of the n⁻-type epitaxial layer 27 embedded in the p-type column trenches 25B becomes unnecessary. Therefore, the number of manufacturing processes are reduced, thereby enabling manufacturing costs to be reduced.

Furthermore, as compared to the multistage epitaxial technique, the respective widths of the n-type column regions 3 and the p-type column regions 4 may be reduced and, for example, in the SJ-MOSFET (superjunction semiconductor device) 50 having a breakdown voltage of at most 100V, reduction of the ON resistance becomes possible. Further, the p-type column regions 4 are formed by diffusion by ion implantation and a heat treatment and therefore, at borders between the p-type column regions 4 and the n-type column regions 3, mutual diffusion occurs. Therefore, when the p-type column regions and the n-type column regions are formed by the conventional trench embedding technique, the conductivity type at the borders between the p-type column regions 4 and the n-type column regions 3 changes gradually. As a result, spreading of a depletion layer is facilitated, electric field is mitigated, and the breakdown voltage may be improved.

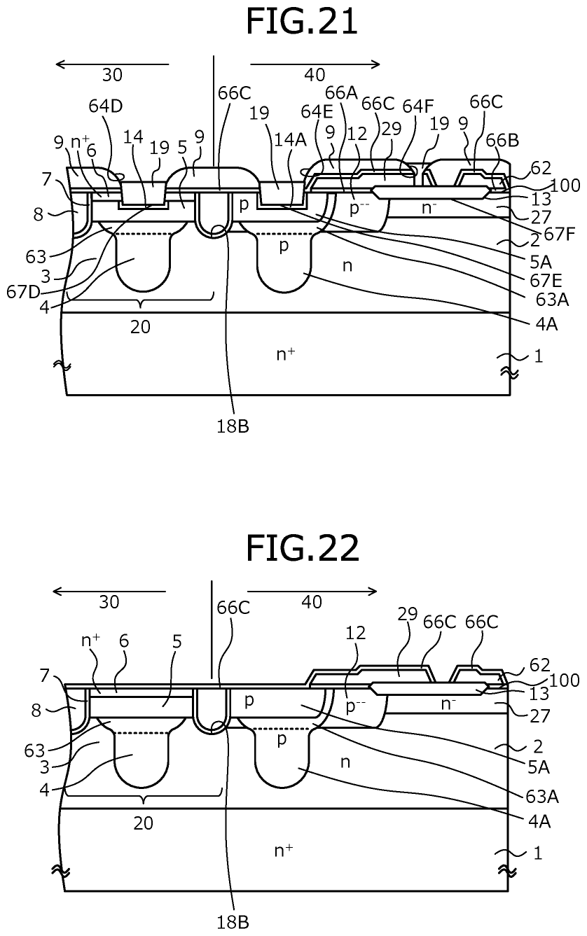

The SJ-MOSFET 50 depicted in FIG. 2C is manufactured as follows. First, similarly to the SJ-MOSFET 50 depicted in FIG. 2A, up to the p-type base regions 5 are formed by performing the same processes depicted in FIGS. 4 to 17. Instead of the processes depicted in FIGS. 18 and 19, the contact plugs 19 are formed by the processes depicted in FIGS. 20 and 21.

After the process depicted in FIG. 17, for example, a resist mask (not depicted) having predetermined openings is formed at upper portions of the p-type base regions 5, via the insulating film 66C, by a photolithographic technique. Ion implantation using the resist mask is performed and an n-type impurity is implanted. The n-type impurity forming the n⁺-type source regions 6 is implanted in surface layers of the p-type base regions 5 of the active region 30. The n-type impurity is, for example, arsenic (As) or phosphorus (P), etc. Thereafter, the resist mask is removed.

Next, for example, a resist mask (not depicted) having predetermined openings is formed at upper portions of the p-type base regions 5, 5A, via the insulating film 66C, by a photolithographic technique. Ion implantation using the resist mask is performed, thereby implanting a p-type impurity. The p-type impurity forming the p⁺⁺-type contact regions 14, 14A is implanted in surface layers of the p-type base regions 5, 5A. The p-type impurity forming the p⁺⁺-type contact regions 14, 14A is implanted at positions deeper than the n-type impurity forming the n⁺-type source regions 6.

In surface layers of the p-type base regions 5A in the edge termination region 40, a p-type impurity forming the p⁺⁺-type contact regions 14A is implanted and the n-type impurity forming the n⁺-type source regions 6 needs not be implanted.

Next, a heat treatment for activating the impurities implanted in the n⁺-type source regions 6 and the p⁺⁺-type contact regions 14 is performed. The heat treatment that activates the implanted impurities has a thermal history smaller than a thermal history of the heat treatment for diffusing the implanted impurities. Bottom surfaces of the p⁺⁺-type contact regions 14 are formed deeper than bottom surfaces of the n⁺-type source regions 6. Further, a sequence in which the ion implantations for forming the n⁺-type source regions 6 and the p⁺⁺-type contact regions 14 are performed may be variously changed. The state up to here is depicted in FIG. 20.

Next, the interlayer insulating film 9 is formed in an entire area of an upper portion of the surface (the top surface 100) of the n⁻-type epitaxial layer 27. The interlayer insulating film 9 is formed so as to cover, via the insulating film 66C, for example, upper portions of the gate insulating films 7, the gate electrodes 8, the n⁺-type source regions 6, the p⁺⁺-type contact regions 14, the p-type base regions 5A, the p⁺⁺-type contact regions 14A, the field oxide film 13, the field plate 29, and the channel stopper 62. The interlayer insulating film 9 contains, for example, a boron phosphorus silicate glass (BPSG), a phosphorus silicate glass (PSG), etc. Further, the interlayer insulating film 9 may be formed as a layered film having, for example, a high temperature oxide (HTO), a non-doped silicate glass (NSG), or a tetraethyl orthosilicate (TEOS) film beneath the BPSG (between the BPSG and the gate electrodes 8). The thickness of the interlayer insulating film 9 suffices to be about 1 μm.

Next, on the interlayer insulating film 9, for example, a resist mask (not depicted) having openings is formed by a photolithographic technique. Next, by anisotropic dry etching using the resist mask, openings are formed in the interlayer insulating film 9 and the insulating film 66C (borders between the insulating film 66C covering upper portions of the gate electrodes 8 and the gate insulating films 7 formed along the inner walls of the trenches 18B are not depicted). Next, recesses 67D, 67E, 67F are formed by anisotropic dry etching. The recesses 67D, 67E, 67F become the recesses 67A, 67B, 67C depicted in FIG. 2C, when the SJ-MOSFET 50 is completed.

In the interlayer insulating film 9 and the insulating film 66C each covering the top surfaces of the gate electrodes 8 embedded in the trenches 18B of the active region 30, the recesses 67D are formed deeper than the top surface 100, between adjacent trenches 18B of the trenches 18B. The n⁺-type source regions 6 and the p⁺⁺-type contact regions 14 are in contact with (exposed at) sidewalls of the recesses 67D. The p⁺⁺-type contact regions 14 are in contact with (exposed at) bottoms of the recesses 67D. The recesses 67D are the contact holes 64D.

Similarly, the recesses 67D are formed deeper than the top surface 100, in the insulating film 66C and the interlayer insulating film 9 between first portions thereof covering the top surfaces of the gate electrodes 8 embedded in the trenches 18B of the active region 30 and second portions thereof adjacent to the first portions and covering the top surfaces of the gate electrodes 8 embedded in the trenches 18B provided at the border between the active region 30 and the edge termination region 40. The n⁺-type source regions 6 and the p⁺⁺-type contact regions 14 are in contact with (exposed at) the sidewalls of the recesses 67D. The p⁺⁺-type contact regions 14 are in contact with (exposed at) the bottoms of the recesses 67D. The recesses 67D are the contact holes 64D.

Between a portion of the interlayer insulating film 9 covering the field plate 29, and the insulating film 66C and each portion of the interlayer insulating film 9 provided so as to cover the top surfaces of the gate electrodes 8 embedded in the trenches 18B provided at the border between the active region 30 and the edge termination region 40, the recesses 67E are formed deeper than the top surface 100. The p^{+±}-type contact regions 14A are in contact with (exposed at) sidewalls and bottoms of the recesses 67E. The recesses 67E are the contact holes 64E.

The recess 67F is formed in the insulating film 66C and the interlayer insulating film 9 covering the channel stopper 62 and the field plate 29. At a bottom of the recess 67F penetrating through the field plate 29, a surface of the field oxide film 13 is exposed. The field plate 29 and the field oxide film 13 are in contact with (exposed at) sidewalls of the recess 67F. The field oxide film 13 is in contact with (exposed at) a bottom of the recess 67F. The recess 67F is the contact hole 64F. The field oxide film 13 does not have to be in contact with sidewalls of the recess 67F.

After dry etching to form the contact holes 64D, 64E, 64F, the resist mask is removed, a heat treatment (reflow) is performed, whereby the interlayer insulating film 9 is planarized.

Next, by sputtering, along the inner walls of the contact holes 64D, 64E, 64F from the surface of the interlayer insulating film 9, a barrier metal (not depicted) is formed by a titanium film (Ti), a titanium nitride film (TiN), or a layered film (for example, Ti/TiN, etc.) of these. Next, via the barrier metal, for example, a tungsten film (W) is formed so as to be embedded in the contact holes 64D, 64E, 64F.

Next, the tungsten film is etched, thereby forming the contact plugs 19 in the contact holes 64D, 64E, 64F. The contact plugs 19 formed in the contact holes 64D are electrically connected to the n⁺-type source regions 6 and the p⁺⁺-type contact regions 14 via the barrier metal (not depicted). Further, the contact plugs 19 formed in the contact holes 64E are electrically connected to the p⁺⁺-type contact regions 14A via the barrier metal (not depicted). Further, the contact plugs 19 formed in the contact hole 64F are electrically connected to the field plate 29, via the barrier metal (not depicted). The state up to here is depicted in FIG. 21.

Next, by sputtering, aluminum or an alloy having aluminum as a main component (Al—Si, Al—Cu, Al—Si—Cu), etc. is deposited in the top surface of the SJ-MOSFET (superjunction semiconductor device) depicted in FIG. 21. Next, the metal film is patterned by a photolithographic technique and an etching technique, thereby forming the source electrode 10, the metal gate runner 61, and the gate electrode pad (not depicted).

The source electrode 10 is electrically connected to the contact plugs 19 that are electrically connected to the p⁺⁺-type contact regions 14. Further, the metal gate runner 61 is electrically connected to the field plate 29. Furthermore, the metal gate runner 61 is electrically connected to the gate electrodes 8, and the gate electrode pad (not depicted) is electrically connected to the metal gate runner 61 and the gate electrodes 8.

Next, by sputtering, the back electrode 11 is formed on the back surface (the back surface of the semiconductor base) of the n⁺-type semiconductor substrate 1. The back electrode 11 may be formed using, for example, a metal film, etc. containing nickel (Ni), titanium (Ti), gold (Au), silver (Ag), aluminum (Al), or an alloy containing aluminum as a main component (Al—Si, Al—Cu, Al—Si—Cu), etc. Further, a layered film of these (for example, Ti/Ni/Au, Al/Ti/Ni/Au, etc.) may be deposited. After the back electrode 11 is formed, a heat treatment is performed, whereby an ohmic contact is formed between the n⁺-type semiconductor substrate 1 and the back electrode 11. Thus, the SJ-MOSFET 50 depicted in FIG. 2C is completed.

The SJ-MOSFET 50 depicted in FIG. 2C may further manufactured as follows. First, similarly to the SJ-MOSFET 50 depicted in FIG. 2A, up to the p-type base regions 5 are formed by performing the same processes depicted in FIGS. 4 to 17. Instead of the processes depicted in FIGS. 18 and 19, the contact plugs 19 are formed by the processes depicted in FIGS. 22, 23, 24, and 25.

After the first method of manufacturing the SJ-MOSFET according to the embodiment is performed up to FIG. 17, on the surfaces of the p-type base regions 5, for example, a mask having predetermined openings (not depicted) is formed by a photolithographic technique using a resist. An n-type impurity is ion-implanted using this resist mask as a mask. By this ion implantation, in surface layers of the p-type base regions 5, the n-type impurity is implanted where the n⁺-type source regions 6 are to be formed. The implanted n-type impurity is arsenic (As), phosphorus (P), etc. In surface layers of the p-type base regions 5A of the edge termination region 40, the n-type impurity forming the n⁺-type source regions 6 does not have to be implanted. Next, the ion implantation mask used for forming the n⁺-type source regions 6 is removed. Next, to form the n⁺-type source regions 6, a heat treatment that activates the implanted impurity is performed. The state up to here is depicted in FIG. 22.

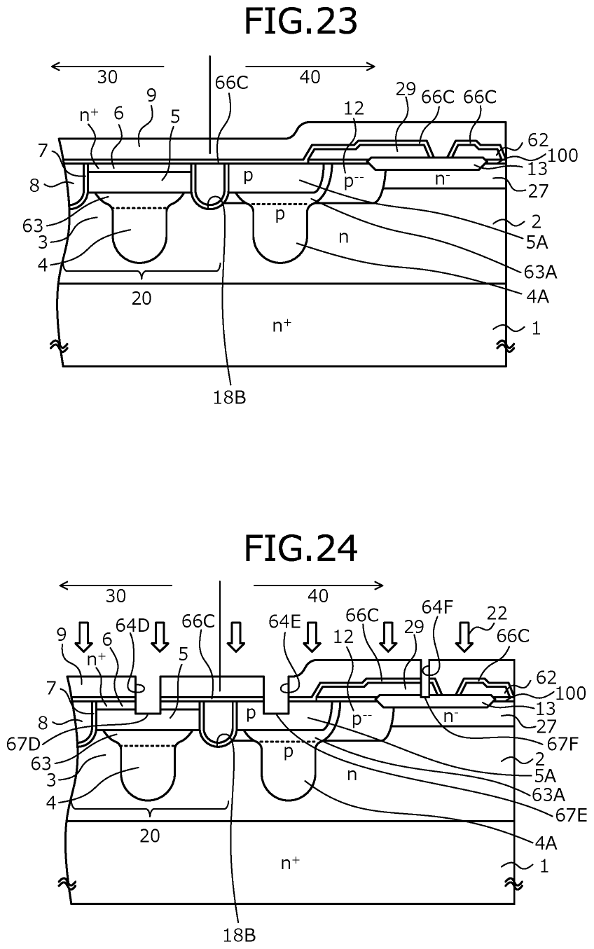

Next, on an entire area of an upper portion of the surface (the top surface 100) of the n⁻-type epitaxial layer 27, the interlayer insulating film 9 is formed. The interlayer insulating film 9, via the insulating film 66C, for example, is formed so as to cover upper portions of the gate insulating films 7, the gate electrodes 8, the n⁺-type source regions 6, the p⁺⁺-type contact regions 14, the p-type base regions 5A, the p⁺⁺-type contact regions 14A, the field oxide film 13, the field plate 29, and the channel stopper 62. Further, the interlayer insulating film 9 may be formed as a layered film having, for example, a high temperature oxide (HTO), a non-doped silicate glass (NSG), or a tetraethyl orthosilicate (TEOS) film beneath the BPSG (between the BPSG and the gate electrodes 8). The thickness of the interlayer insulating film 9 suffices to be about 1 μm. The state up to here is depicted in FIG. 23.

Next, on the surface of the interlayer insulating film 9, for example, by a photolithographic technique, a resist mask (not depicted) having openings is formed. Next, by anisotropic dry etching using the resist mask, openings are formed in the interlayer insulating film 9 and the insulating film 66C (borders between the gate insulating films 7 formed along the inner walls of the trenches 18B and the insulating film 66C covering upper portions of the gate electrodes 8 are not depicted). Next, by anisotropic dry etching, the recesses 67D, 67E, 67F are formed. The recesses 67D, 67E, 67F become the recesses 67A, 67B, 67C in FIG. 2C when the SJ-MOSFET 50 is completed.

In the insulating film 66C and the interlayer insulating film 9 covering the top surfaces of the gate electrodes 8 embedded in the trenches 18B of the active region 30, between adjacent trenches 18B of the trenches 18B, the recesses 67D are formed deeper than the top surface 100. The n⁺-type source regions 6 and the p-type base regions 5 are in contact with (exposed at) the sidewalls of the recesses 67D. The p-type base regions 5 are in contact with (exposed at) the bottoms of the recesses 67D. The recesses 67D are the contact holes 64D.

Similarly, the recesses 67D are formed deeper than the top surface 100, the insulating film 66C and in the interlayer insulating film 9 between first portions thereof covering the top surfaces of the gate electrodes 8 embedded in the trenches 18B of the active region 30 and the second portions thereof adjacent to the first portions and covering the top surfaces of the gate electrodes 8 embedded in the trenches 18B provided at the border between the active region 30 and the edge termination region 40. The n⁺-type source regions 6 and the p-type base regions 5 are in contact with (exposed at) the recesses 67D. The p-type base regions 5 are in contact with (exposed at) the bottoms of the recesses 67D. The recesses 67D are the contact holes 64D.

Between a portion of the interlayer insulating film 9 covering the field plate 29, and the insulating film 66C and each of the portions of the interlayer insulating film 9 provided so as to cover the top surfaces of the gate electrodes 8 embedded in the trenches 18B provided at the border between the active region 30 and the edge termination region 40, the recesses 67E are formed deeper than the top surface 100. The p-type base regions 5A are in contact with (exposed at) the sidewalls and the bottoms of the recesses 67E. The recesses 67E are the contact holes 64E.

The recess 67F is formed in the insulating film 66C and the interlayer insulating film 9 covering the channel stopper 62 and the field plate 29. At the bottom of the recess 67F penetrating through the field plate 29, the surface of the field oxide film 13 is exposed. The field plate 29 and the field oxide film 13 are in contact with (exposed at) the recess 67F. The field oxide film 13 are in contact with (exposed at) the bottom of the recess 67F. The recess 67F is the contact hole 64F. The field oxide film 13 does not have to be in contact with the sidewall of the recess 67F.

Next, the ion implantation 22 is performed using the interlayer insulating film 9 as a mask and a p-type impurity is implanted. At the bottoms of the recesses 67D and the sidewalls and the bottoms of the recesses 67E, the p-type impurity forming the p⁺⁺-type contact regions 14, 14A is implanted in surface layers of the p-type base regions 5, 5A. In the surface layers of the p-type base regions 5A of the edge termination region 40, the p-type impurity forming the p⁺⁺-type contact regions 14A is implanted and the n-type impurity forming the n⁺-type source regions 6 needs not be implanted. The state up to here is depicted in FIG. 24.

Next, a heat treatment (reflow) is performed, whereby the interlayer insulating film 9 is planarized. Further, concurrently with planarization of the interlayer insulating film 9, the implanted p-type impurity forming the p⁺⁺-type contact regions 14, 14A may be activated.

Next, by sputtering, along the inner walls of the contact holes 64D, 64E, 64F from the surface of the interlayer insulating film 9, the barrier metal (not depicted) is formed by a titanium film (Ti), a titanium nitride film (TiN), or a layered film (for example, Ti/TiN, etc.) of these. Next, via the barrier metal, for example, a tungsten film (W) is formed so as to be embedded in the contact holes 64D, 64E, 64F.

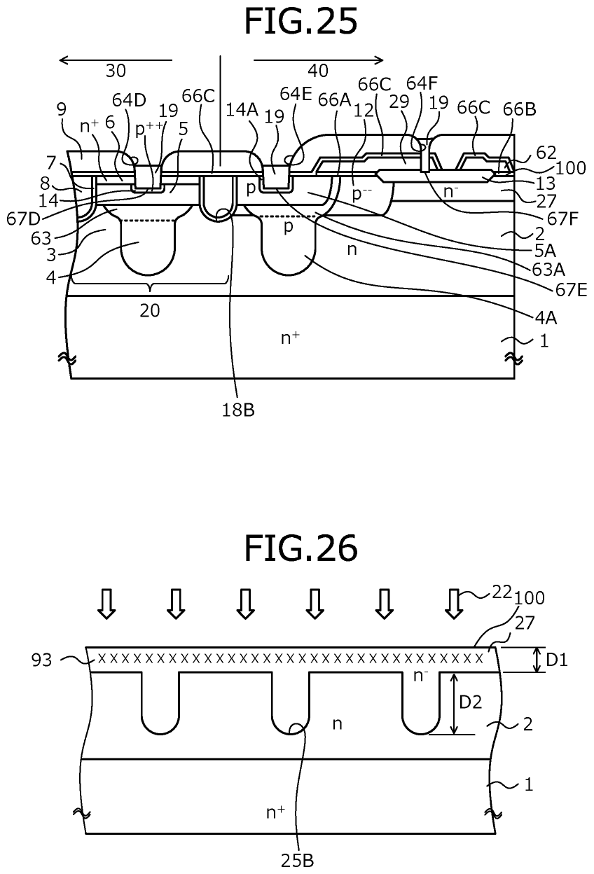

Next, the tungsten film is etched, thereby forming the contact plugs 19 in the contact holes 64D, 64E, 64F. The contact plugs 19 formed in the contact holes 64D are electrically connected to the n⁺-type source regions 6 and the p⁺⁺-type contact regions 14 via the barrier metal (not depicted). Further, the contact plugs 19 formed in the contact holes 64E are electrically connected to the p⁺⁺-type contact regions 14A via the barrier metal (not depicted). Further, the contact plugs 19 formed in the contact hole 64F are electrically connected to the field plate 29, via the barrier metal (not depicted). The state up to here is depicted in FIG. 25.

Next, by sputtering, aluminum or an alloy having aluminum as a main component (Al—Si, Al—Cu, Al—Si—Cu), etc. is deposited in the top surface of the SJ-MOSFET (superjunction semiconductor device) depicted in FIG. 25. Next, the metal film is patterned by a photolithographic technique and an etching technique, thereby forming the source electrode 10, the metal gate runner 61, and the gate electrode pad (not depicted).

The source electrode 10 is electrically connected to the contact plugs 19 that are electrically connected to the p⁺⁺-type contact regions 14. Further, the metal gate runner 61 is electrically connected to the field plate 29. Furthermore, the metal gate runner 61 is electrically connected to the gate electrodes 8, and the gate electrode pad (not depicted) is electrically connected to the metal gate runner 61 and the gate electrodes 8.

Next, by sputtering, the back electrode 11 is formed on the back surface (the back surface of the semiconductor base) of the n⁺-type semiconductor substrate 1. The back electrode 11 may be formed using, for example, a metal film, etc. containing nickel (Ni), titanium (Ti), gold (Au), silver (Ag), aluminum (Al), or an alloy containing aluminum as a main component (Al—Si, Al—Cu, Al—Si—Cu), etc. Further, a layered film of these (for example, Ti/Ni/Au, Al/Ti/Ni/Au, etc.) may be deposited. After the back electrode 11 is formed, a heat treatment is performed, whereby an ohmic contact is formed between the n⁺-type semiconductor substrate 1 and the back electrode 11. Thus, the SJ-MOSFET 50 depicted in FIG. 2C is completed.

Next, a second method of manufacturing different from the first method of manufacturing depicted in FIGS. 4 to 21 is described. FIGS. 26, 27, 28, 29, and 30 are cross-sectional views of states of the SJ-MOSFET according to the embodiment during manufacture by the second method of manufacturing. The second method of manufacturing is a method of manufacturing the SJ-MOSFET depicted in FIG. 2D. A method of manufacturing the edge termination region 40 is similar to that of the first method of manufacturing and therefore, FIGS. 26 to 30 depict cross-sectional views of the active region 30. In the second method of manufacturing, processes similar to those of the first method of manufacturing up to the processes depicted in FIGS. 4 to 8 are performed, whereby the n⁻-type epitaxial layer 27 is formed.

The second method of manufacturing differs from the first method of manufacturing in that an implanted region 93 is formed in the n⁻-type epitaxial layer 27 by the ion implantation 22. In particular, in the section D1, the ion implantation 22 is performed in an entire area of a predetermined region that excludes a portion of the edge termination region 40, thereby forming the implanted region 93. The predetermined region is closer to a center of the active region 30 than are openings of the ion implantation mask 21 for forming the p-type column regions 4A depicted in FIG. 9A.

Here, a depth indicates a direction from the top surface 100 (surface) of the n⁻-type epitaxial layer 27 toward the front surface of the n⁺-type semiconductor substrate 1. An implantation depth is a depth of implantation an impurity from the top surface 100 (surface) of the n⁻-type epitaxial layer 27 (position of a peak of the impurity concentration distribution).

Further, the implanted region 93 formed by performing the ion implantation 22 indicates a region implanted with an impurity from the top surface 100 (position of a peak of the impurity concentration distribution). An implantation depth indicates a depth from the top surface 100 (surface) of the n⁻-type epitaxial layer 27 to the implanted region 93 formed in the n⁻-type epitaxial layer 27.

Furthermore, between the surface (the top surface 100) of the n⁻-type epitaxial layer 27 and the surface of the n-type drift layer 2 (the thickness T1 of the flat portion of the n⁻-type epitaxial layer 27) is assumed as the section D1, and from the surface of the n-type drift layer 2 to the bottoms of the p-type column trenches 25B (depth of the p-type column trenches 25B) is assumed as the sections D2.

After the process for forming the n⁻-type epitaxial layer 27 depicted in FIG. 8, the ion implantation 22 of a p-type impurity in a predetermined region from the surface of the n⁻-type epitaxial layer 27 is performed. The p-type impurity is, for example, boron (B) or aluminum (Al), etc. In the second method of manufacturing, the ion implantation 22 is performed in a predetermined region of the n⁻-type epitaxial layer 27; and in a region closer to an outer periphery than are openings of the ion implantation mask 21 for forming the p-type column regions 4A of the edge termination region 40 in which the ion implantation depicted in FIG. 9A is not performed, an ion implantation mask needs not be newly formed. In the region of the outer periphery in which the ion implantation 22 is not performed, the oxide film 23 depicted in FIG. 6 may be left as a mask, so that a p-type impurity is not implanted. Further, in the outer peripheral region, the ion implantation mask 21 may be formed on the surface (the top surface 100) of the n⁻-type epitaxial layer 27 by a resist and the ion implantation 22 may be performed.

The implanted region 93 formed by the ion implantation 22 is formed in the section D1. In an instance in which the section D1 is 0.8 μm and the sections D2 are each 1.0 μm, the depth from the surface of the n⁻-type epitaxial layer 27 to the implanted region 93 is assumed to be 0.4 μm. The section D1 (the thickness T1) suffices to be in a ranged from 0.5 μm to 1.0 μm. The implantation depth from the surface (the top surface 100) of the n⁻-type epitaxial layer 27 to the implanted region 93 suffices to be in a range from 0.2 μm to 1.0 μm. Further, the sections D2 suffice to be in a range from 0.5 μm to 2.0 μm. The implanted region 93 may be formed at the border between the section D1 and the sections D2. The state up to here is depicted in FIG. 26.

Next, a mask (not depicted) used for the ion implantation 22, for example, the ion implantation mask 21, etc. formed by a resist, the oxide film 23, etc. is removed and thereafter, a heat treatment is performed and the p-type impurity is diffused. As a result, the p-type column regions 4 and the p-type well regions 63 are formed.

Here, the n⁻-type epitaxial layer 27 is formed having an impurity concentration lower than the impurity concentration of the n-type drift layer 2. By the ion implantation 22 of the p-type impurity and the heat treatment thereafter, the p-type impurity spreads easily in the n⁻-type epitaxial layer 27 from the implanted region 93.

Regions between adjacent p-type column regions 4 of the p-type column regions 4 become the n-type column regions 3, whereby the parallel pn region 20 is formed. The p-type well regions 63 are formed in an entire area of a predetermined region subject to the ion implantation 22.

The impurity concentration of the p-type well regions 63 and the p-type column regions 4 is highest in the implanted region 93 and in the depth direction, decreases with increasing distance from the implanted region 93. Here, the depth direction is a direction from the surface of the n⁻-type epitaxial layer 27 toward the n⁺-type semiconductor substrate 1.

After the heat treatment for diffusing the p-type impurity after the ion implantation 22, the oxide film 28 is formed on surfaces of the p-type well regions 63 (the top surface 100). The oxide film 28 may be formed by the heat treatment for diffusing the p-type impurity after the ion implantation 22.

When the heat treatment is performed, a shape of borders between the p-type column regions 4 and the p-type well regions 63 (corner portions between the p-type column trenches 25B and the surface of the n-type drift layer 2) may be formed to be curved due to diffusion of the impurity. The state up to here is depicted in FIG. 27.

In this manner, by the second method of manufacturing, before the trenches 18A described hereinafter are formed, the ion implantation 22 is performed in an entire area of a predetermined region excluding a portion of the edge termination region 40, whereby the implanted region 93 is formed. A heat treatment is performed after the ion implantation 22, thereby forming the p-type column regions 4 and the p-type well regions 63.

The n⁻-type epitaxial layer 27 is formed to have an impurity concentration lower than the impurity concentration of the n-type drift layer 2. A concentration difference between the impurity concentration of the n⁻-type epitaxial layer 27 and the impurity concentration of the n-type drift layer 2 is large and therefore, the p-type impurity implanted by the ion implantation 22 does not easily diffuse in the n-type drift layer 2 and easily diffuses in the n⁻-type epitaxial layer 27.

The p-type well regions 63 are formed in an entire area of a predetermined region subject to the ion implantation 22 and are in contact with the sidewalls of the trenches 18B and therefore, have a similar function as the p-type base regions 5 formed by a subsequent process. The p-type impurity implanted by the ion implantation 22 does not diffuse easily in the n-type drift layer 2 and therefore, widening of the channel length due to heat treatment may be suppressed.

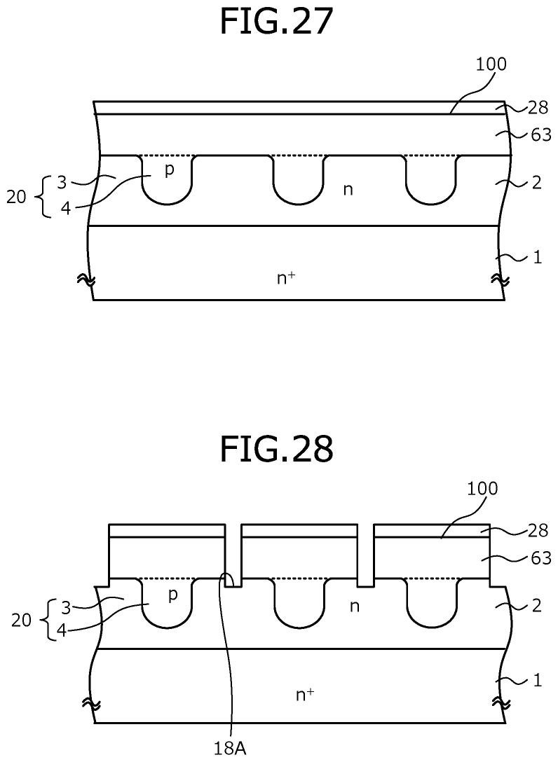

Next, on the surface of the oxide film 28, a photoresist mask (not depicted) having predetermined openings is formed by a photolithographic technique. Next, openings are formed in the oxide film 28 by, for example, anisotropic dry etching using the photoresist mask. Next, the photoresist mask (not depicted) is removed and the trenches 18A that penetrate the p-type well regions 63 and reach the n-type drift layer 2 (the n-type column regions 3) are formed by anisotropic dry etching using the oxide film 28. In the second method of manufacturing, the p-type well regions 63 are in contact with the trenches 18A. The state up to here is depicted in FIG. 28.

Next, with the oxide film 28 attached, isotropic etching and sacrificial oxidation are performed. By these processes, damage of the trenches 18A is removed and the bottoms of the trenches 18A become curved. As for a sequence in which the isotropic etching and the sacrificial oxidation are performed, either may be performed first. Further, either the isotropic etching or the sacrificial oxidation alone may be performed. Thereafter, the oxide film 28 is removed. The sacrificial oxide film (not depicted) may be removed concurrently with the oxide film 28.

Next, along the surfaces of the p-type well regions 63 (the top surface 100 of the n⁻-type epitaxial layer 27) and the inner walls of the trenches 18B, the gate insulating films 7 are formed. The gate insulating films 7 may be formed by thermal oxidation of a temperature of about 1000 degrees C. under an oxygen atmosphere. Further, the gate insulating films 7 may be formed by a deposition method by a chemical reaction such as that for a high temperature oxide (HTO), etc.

Next, on the gate insulating films 7, for example, a polycrystalline silicon layer doped with phosphorus atoms is provided. The polycrystalline silicon layer is formed so as to be embedded in the trenches 18B. The polycrystalline silicon layer is patterned by a photolithographic technique and an etching technique, thereby forming the gate electrodes 8 in the trenches 18B, via the gate insulating films 7. The p-type well regions 63 are in contact with the sidewalls of the trenches 18B.

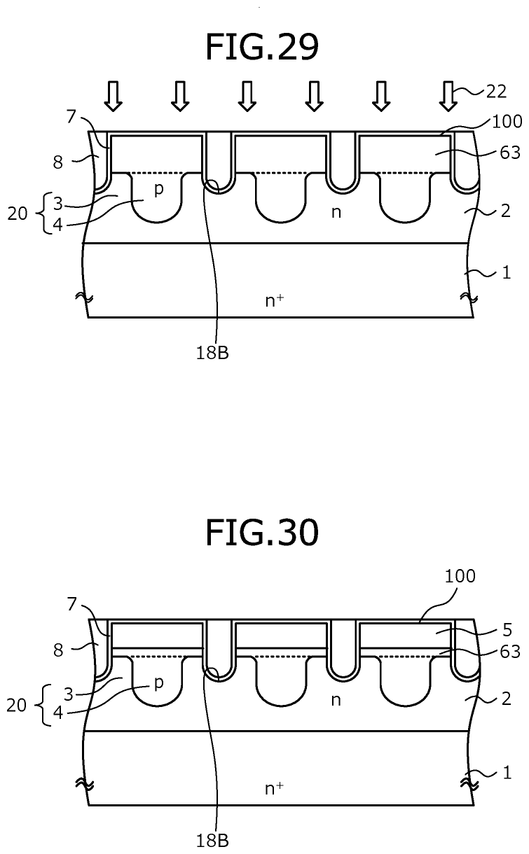

Next, from the surfaces of the p-type well regions 63 (the top surface 100 of the n⁻-type epitaxial layer 27), the ion implantation 22 of a p-type impurity, for example, boron (B), etc. for forming the p-type base regions 5 is performed. In the active region 30, the gate electrodes 8 function as a mask. The state up to here is depicted in FIG. 29.

Next, a heat treatment for diffusing the p-type impurity implanted by the ion implantation 22 is performed, whereby the p-type base regions 5 are formed. The p-type base regions 5 are formed in surface layers of the p-type well regions 63 and the impurity concentration of the p-type base regions 5 is higher than the impurity concentration of the p-type well regions 63. In the depth direction, the bottom surfaces of the p-type base regions 5 are formed to be shallower than the bottom surfaces of the p-type well regions 63. The p-type base regions 5 and the p-type well regions 63 are formed to be in contact with the sidewalls of the trenches 18B.

Similarly, the p-type base regions 5 and the p-type well regions 63 are in contact with first sidewalls of the trenches 18B (not depicted) formed at the border between the active region 30 and the edge termination region 40, the first sidewalls being in the active region 30; and in the edge termination region 40, the p-type base regions 5A and the p-type well regions 63A are in contact with second sidewalls of the trenches 18B in the edge termination region 40.

In an instance in which the trenches 18B are formed after the p-type well regions 63 are formed, due to processes in which the SJ-MOSFET (superjunction semiconductor device) 50 is heated, for example, for formation of the oxide film 28, a sacrificial oxide film, and the gate insulating films 7, etc., the p-type impurity of the p-type well regions 63 may diffuse and variation of the gate threshold voltage may increase. Therefore, after formation of the trenches 18B (formation of the gate electrodes 8), the p-type base regions 5 are formed, thereby enabling stabilization of the gate threshold voltage. The state up to here is depicted in FIG. 30.

In an instance in which the ion implantation 22 of a p-type impurity for forming the p-type base regions 5 is not performed, the number of ion implantations may be reduced, thereby enabling manufacturing cost to be reduced. Subsequently, similarly to the first method of manufacturing, the process of forming the n⁺-type source regions 6 and subsequent processes are performed, whereby the SJ-MOSFET 50 depicted in FIG. 2D is completed. In the second method of manufacturing, the p-type well regions 63 differ from those of the first method of manufacturing and the p-type well regions 63 are in contact with the sidewalls of the trenches 18B.

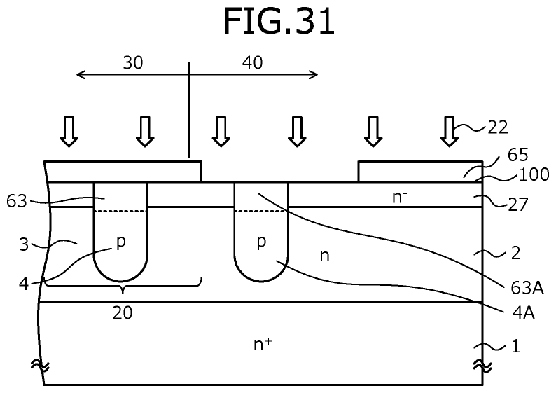

Next, a third method of manufacturing different from the second method of manufacturing depicted in FIGS. 26 to 30 is described. FIGS. 31, 32, 33, 34, 35, 36, 37, 38, and 39 are cross-sectional views of states of the SJ-MOSFET according to the embodiment during manufacture by the third method of manufacturing. The third method of manufacturing is a method of manufacturing the SJ-MOSFET depicted in FIG. 2B. In the third method of manufacturing, first, processes similar to the processes depicted in FIGS. 4 to 8, FIG. 9C, and FIG. 10C of the first method of manufacturing are performed and the p-type impurity is diffused by a heat treatment.

The third method of manufacturing differs from the first method of manufacturing in that the p-type column regions 4, 4A are formed by performing ion implantation of an impurity of the second conductivity type in only regions in which the n⁻-type epitaxial layer 27 is embedded in the p-type column trenches 25B.

Next, on the surface (the top surface 100) of the n⁻-type epitaxial layer 27, the ion implantation mask 65 having an opening for forming the p⁻⁻-type RESURF region 12 is formed by a photolithographic technique. The ion implantation mask 65 is, for example, a photoresist. A p-type impurity is ion-implanted using the ion implantation mask 65 as a mask. The p-type impurity is, for example, boron (B) or aluminum (Al), etc. The state up to here is depicted in FIG. 31.

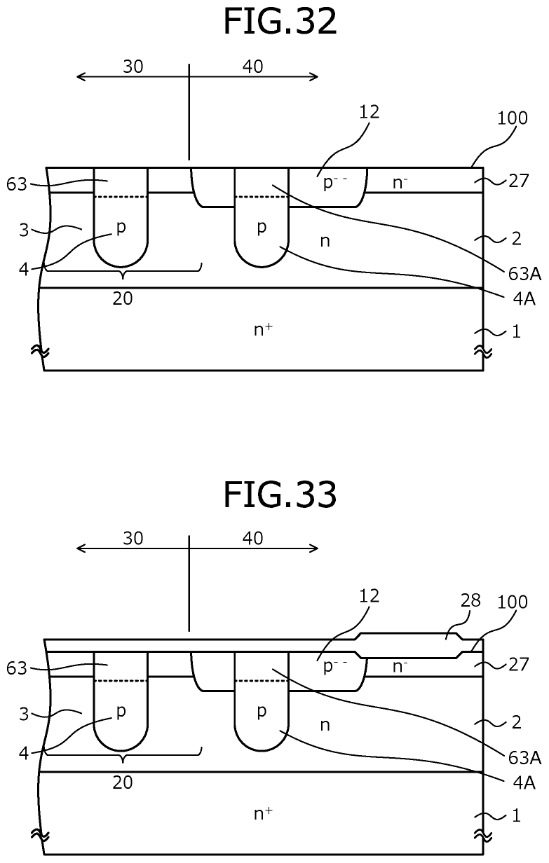

Next, the ion implantation mask 65 is removed and thereafter, a heat treatment for diffusing the implanted p-type impurity is performed, thereby forming the p⁻⁻-type RESURF region 12 in a surface layer of the n⁻-type epitaxial layer 27. The p⁻⁻-type RESURF region 12 has an impurity concentration lower than the impurity concentration of the p-type well regions 63A and therefore, the p⁻-type RESURF region 12 is not formed in the p-type well regions 63A. The bottom surface of the p⁻⁻-type RESURF region 12 is formed deeper than the border between the n⁻-type epitaxial layer 27 and the n-type drift layer 2. Further, the bottom surface of the p⁻⁻-type RESURF region 12 may be formed deeper or shallower than the borders between the p-type column regions 4A and the p-type well regions 63A (dashed lines). The state up to here is depicted in FIG. 32.

Next, on the top surface 100, the oxide film 28 is formed. The oxide film 28 may be, for example, a LOCOS film. The oxide film 28 is formed so that a thickness of a portion thereof in the active region 30 is less than the thickness of the thick portion of the oxide film 28 formed closer to the outer periphery of the edge termination region 40. The oxide film 28 is formed so that the thick portion where the thickness thereof is thick is at the top surface of the n⁻-type epitaxial layer 27 and the bottom surface of the thick portion of the oxide film 28 is formed at a position deeper than is the top surface 100. In the thick portion of the oxide film 28, an end thereof facing the active region 30 is formed so that continuously from the end to a portion of the bottom surface thereof is covered by the p⁻⁻-type RESURF region 12 therebelow. Further, the other end of the thick portion of the oxide film 28 is formed so that continuously from the other end to a portion of the bottom surface thereof is covered by the n⁻-type epitaxial layer 27 therebelow. The state up to here is depicted in FIG. 33.

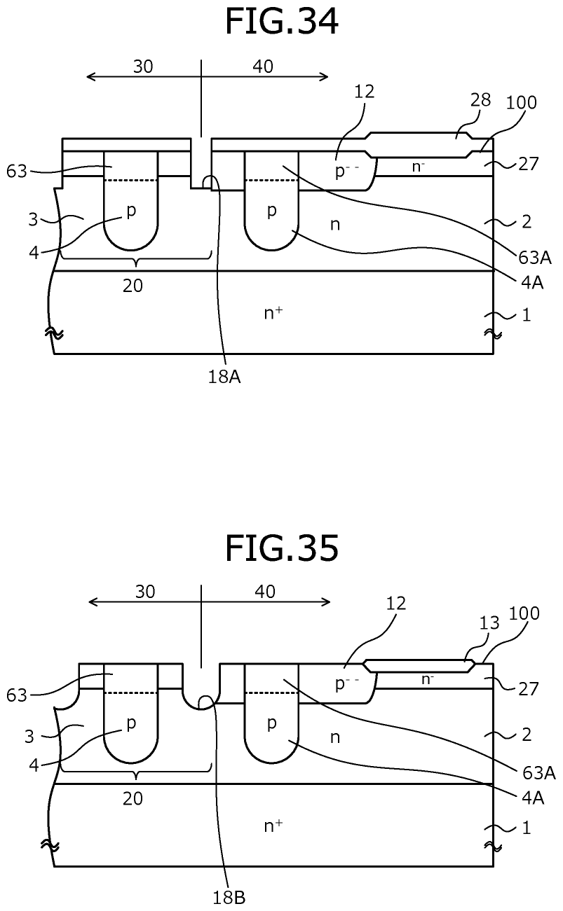

Next, on the surface of the oxide film 28, a resist mask (not depicted) having predetermined openings is formed by a photolithographic technique. Next, openings are formed in the oxide film 28 by dry etching using the resist mask as a mask. Next, the resist mask is removed and the trenches 18A that penetrate the n⁻-type epitaxial layer 27 from the top surface 100 of the n⁻-type epitaxial layer 27 and reach the n-type drift layer 2 are formed by anisotropic dry etching using the oxide film 28 as a mask. The state up to here is depicted in FIG. 34.

Next, with the oxide film 28 attached as is, isotropic etching and sacrificial oxidation are performed. By these processes, damage of the trenches 18A is removed and bottoms of the trenches 18A become curved. As for a sequence in which the isotropic etching and the sacrificial oxidation are performed, either may be performed first. Further, the isotropic etching or the sacrificial oxidation alone may be performed. Thereafter, a portion of the oxide film 28 where the thickness thereof is thin and used for forming the trenches 18A is removed. At this time, the sacrificial oxide film may be removed concurrently with the portion of the oxide film 28 where the thickness thereof is thin. The trenches 18A after the oxide film 28 is removed become the trenches 18B. The oxide film 28 has the portion where the thickness thereof is thin and the portion where the thickness thereof is thick in the edge termination region 40 and therefore, an entire area of the surface of the portion thereof where the thickness thereof is thin is etched and removed, leaving the thick portion of the oxide film 28 where the thickness thereof is thick in the edge termination region 40. The sacrificial oxide film (not depicted) may be removed together with the portion of the oxide film 28 where the thickness thereof is thin. Further, the oxide film 28 may be removed by a photolithographic technique and an etching technique, to thereby leave the oxide film 28 in the edge termination region 40. The oxide film 28 left in the edge termination region 40 (the portion of the oxide film 28 where the thickness thereof is thick) becomes the field oxide film 13. The state up to here is depicted in FIG. 35.

Next, the gate insulating films 7 are formed along the surfaces (the top surface 100) of the n⁻-type epitaxial layer 27, the p⁻⁻-type RESURF region 12, and the p-type well regions 63, 63A, and along inner walls of the trenches 18B. The gate insulating films 7 may be formed by thermal oxidation of a temperature of about 1000 degrees C. under an oxygen atmosphere. Further, the gate insulating films 7 may be formed by a deposition method by a chemical reaction such as that for a high temperature oxide (HTO).

Next, on the gate insulating films 7, for example, a polycrystalline silicon layer doped with phosphorus atoms is provided. The polycrystalline silicon layer is formed so as to be embedded in the trenches 18B. The polycrystalline silicon layer is patterned by a photolithographic technique and an etching technique, thereby forming the gate electrodes 8 in the trenches 18B via the gate insulating films 7.

Further, the polycrystalline silicon layer formed in the edge termination region 40 may be selectively left as the field plate 29 and the channel stopper 62.

The field plate 29 is formed continuously on the top surfaces of the gate insulating films 7 (the insulating film 66A) formed on the p⁻⁻-type RESURF region 12, the p-type well regions 63A, and the p-type base regions 5A (the top surface 100), and the top surface of a portion of the field oxide film 13 closer to the active region 30 than to the outer periphery of the edge termination region 40. The field plate 29 is electrically connected to the gate electrodes 8 and has a function of gate wiring.

The channel stopper 62 is formed continuously on the top surface of an outer peripheral side of the field oxide film 13 and the top surfaces of the gate insulating films 7 (the insulating film 66B) formed on the n⁻-type epitaxial layer 27 (the top surface 100). The field plate 29 and the channel stopper 62 are separate from each other on the field oxide film 13.

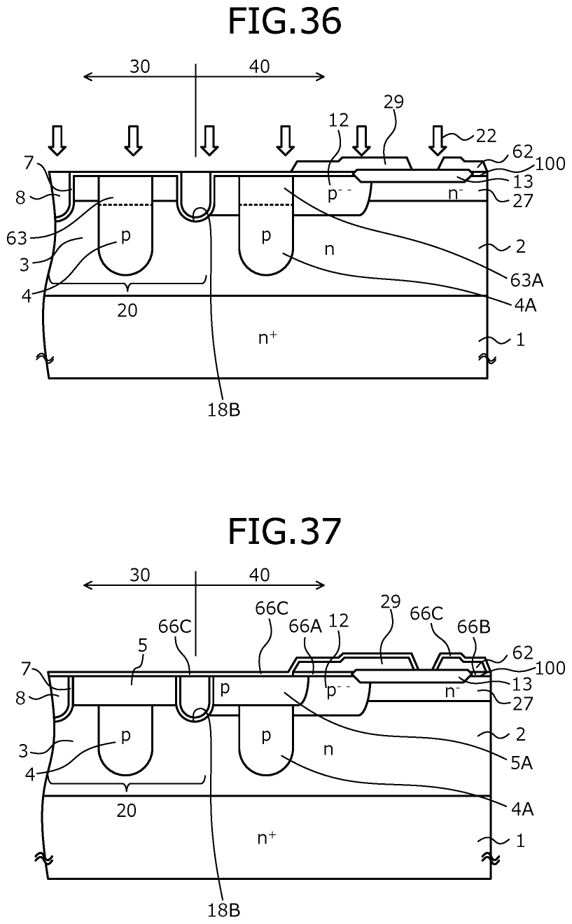

Next, from the top surface 100 of the n⁻-type epitaxial layer 27 (surfaces of the p-type well regions 63, 63A, and the n⁻-type epitaxial layer 27), the ion implantation 22 of a p-type impurity for forming the p-type base regions 5, 5A is performed. The p-type impurity is, for example, boron (B) or aluminum (Al), etc. At this time, on the n⁻-type epitaxial layer 27 in the edge termination region 40, the field plate 29, the channel stopper 62, and the field oxide film 13 function as a mask. Therefore, the p-type impurity is not implanted in the n⁻-type epitaxial layer 27. Further, the gate electrodes 8 also function as a mask. The state up to here is depicted in FIG. 36.

Next, removal of the gate insulating films 7 formed on the top surface 100 is performed. The removal of the gate insulating films 7 needs not be performed when the thickness of the gate insulating films 7 is a thickness that does not obstruct the ion implantation for forming the n⁺-type source regions 6, as described hereinafter, for example, a thickness that is at most 500 Å.

Next, the p-type impurity is diffused by a heat treatment, whereby the p-type base regions 5, 5A are formed in surface layers of the n⁻-type epitaxial layer 27, the p-type well regions 63, 63A, and the p⁻⁻-type RESURF region 12. By this heat treatment, an insulating film 66C is formed so as to cover the top surfaces of the field plate 29, the channel stopper 62 and the gate electrodes 8 formed by the polycrystalline silicon layer that is formed so as to be embedded in the trenches 18B.

The p-type base regions 5 and the p-type well regions 63 overlap one another and the bottom surfaces of the p-type base regions 5 are formed shallower than the bottom surfaces of the p-type well regions 63. The p-type base regions 5A and the p-type well regions 63A overlap one another and the bottom surfaces of the p-type base regions 5A are formed shallower than the bottom surfaces of the p-type well regions 63A.

The impurity concentration of the p-type base regions 5 and the impurity concentration of the p-type base regions 5A may be equal to each other. The impurity concentration of the p-type well regions 63 and the impurity concentration of the p-type well regions 63A may be equal to each other. The impurity concentration of the p-type base regions 5 is higher than the impurity concentration of the p-type well regions 63. Further, the impurity concentration of the p-type base regions 5A is higher than the impurity concentration of the p-type well regions 63A. The p-type base regions 5, 5A are formed to be in contact with the sidewalls of the trenches 18B.

In the edge termination region 40, the oxide film 28, the field plate 29, and the channel stopper 62 function as a mask and therefore, boron (B) is not implanted in upper portions of the n⁻-type epitaxial layer 27 or the p⁻⁻-type RESURF region 12 covered by the oxide film 28, the field plate 29, or the channel stopper 62. As a result, even when the heat treatment for diffusing the p-type impurity to form the p-type base regions 5, 5A is performed, the p-type impurity that forms the p-type base regions 5, 5A does not diffuse into the n⁻-type epitaxial layer 27 or the p⁻⁻-type RESURF region 12. Therefore, the n⁻-type epitaxial layer 27 and the p⁻⁻-type RESURF region 12 remain in the edge termination region 40.

In this manner, in the third method of manufacturing, the p-type base regions 5 where the channels are formed are formed after the formation of the trenches 18B. The state up to here is depicted in FIG. 37.

Next, on the surfaces of the p-type base regions 5, for example, a mask having predetermined openings (not depicted) is formed by a photolithographic technique using a resist. An ion implantation of an n-type impurity is performed using the resist mask as a mask. By this ion implantation, the n-type impurity is implanted at places where the n⁺-type source regions 6 are to be formed in surface layers of the p-type base regions 5. The implanted n-type impurity is arsenic (As), phosphorus (P), etc.

Next, the ion implantation mask used for forming the n⁺-type source regions 6 is removed. Further, on the surfaces of the p-type base regions 5, for example, a mask having predetermined openings may be formed by a photolithographic technique using a resist and a p-type impurity may be implanted forming, in surface layers of the p-type base regions 5, the p⁺⁺-type contact regions 14 in contact with the n⁺-type source regions 6. Further, in surface layers of the p-type base regions 5A as well, a p-type impurity may be implanted forming the p⁺⁺-type contact regions 14A. The n⁺-type source regions 6 are not formed in surface layers of the p-type base regions 5A in the edge termination region 40.

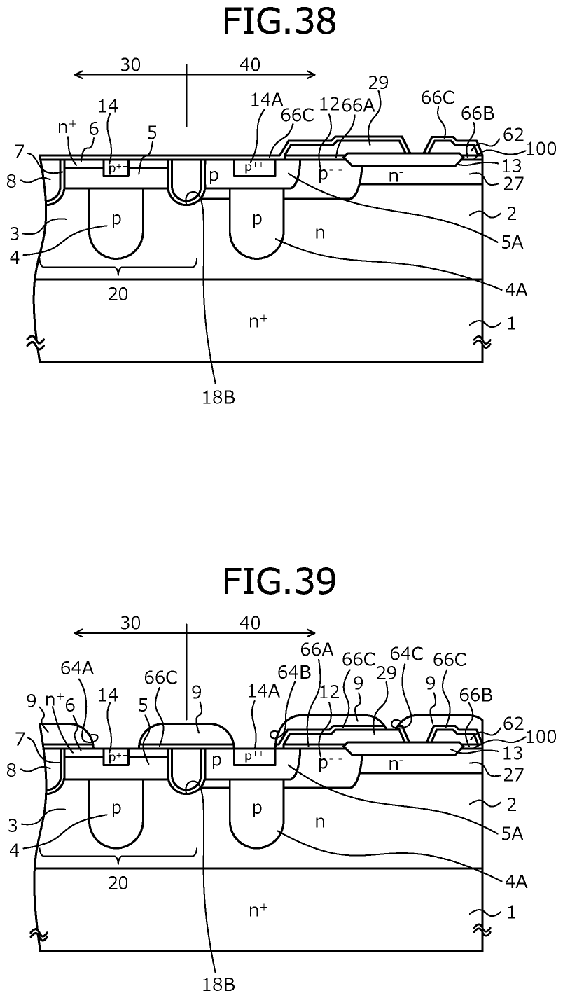

Next, a heat treatment for activating the impurities implanted in the n⁺-type source regions 6 and the p⁺⁺-type contact regions 14, 14A is performed. The heat treatment that activates the implanted impurities has a thermal history smaller than the thermal history of the heat treatment for diffusing the implanted impurities. As for a sequence in which the ion implantations for forming the n⁺-type source regions 6 and the p⁺⁺-type contact regions 14, 14A are performed, either may be performed first. The state up to here is depicted in FIG. 38.

Next, the interlayer insulating film 9 is formed in an entire area of an upper portion of the surface (the top surface 100) of the n⁻-type epitaxial layer 27. The interlayer insulating film 9 is formed so as to cover, via the insulating film 66C, for example, the gate insulating films 7, the gate electrodes 8, the n⁺-type source regions 6, the p⁺⁺-type contact regions 14, the p-type base regions 5A, the p⁺⁺-type contact regions 14A, the field oxide film 13, the field plate 29, and the channel stopper 62. The interlayer insulating film 9 contains, for example, BPSG, PSG, etc. Further, the interlayer insulating film 9 may be formed as a layered film having, for example, a HTO, a NSG, or a TEOS film beneath the BPSG (between the BPSG and the gate electrodes 8). The thickness of the interlayer insulating film 9 suffices to be about 1 μm.

Next, the interlayer insulating film 9 and the insulating film 66C are patterned by a photolithographic technique and an etching technique. In the active region 30, the contact holes 64A that expose the surfaces of the n⁺-type source regions 6 and the p⁺⁺-type contact regions 14 are formed (borders between the interlayer insulating film 9 covering the upper portions of the gate electrodes 8 and the gate insulating films 7 formed along the inner walls of the trenches 18B are not depicted). Further, in the edge termination region 40, the contact holes 64B that expose the surfaces of the p⁺⁺-type contact regions 14A are formed. Further, in the edge termination region 40, the contact hole 64C that exposes the surface of the field plate 29 is formed. Thereafter, a heat treatment (reflow) is performed, thereby planarizing the interlayer insulating film 9. The state up to here is depicted in FIG. 39.

Next, by sputtering, aluminum or an alloy having aluminum as a main component (Al—Si, Al—Cu, Al—Si—Cu), etc. is embedded in the contact holes 64A, 64B, 64C and is further deposited so as to be continuous on the top surface of the interlayer insulating film 9. Before the metal film is deposited, by sputtering, a barrier metal (not depicted) may be formed by a titanium film (Ti), a titanium nitride film (TiN), or a layered film of these (for example, Ti/TiN, etc.) so as to be continuous along inner walls of the contact holes 64A, 64B, 64C and on the top surface of the interlayer insulating film 9. Thereafter, the metal film and the barrier metal (not depicted) are patterned by a photolithographic technique and an etching technique, whereby the source electrode 10, the metal gate runner 61, and a gate electrode pad (not depicted) are formed. Configuration may be such that the barrier metal is formed in only the contact holes 64A, 64B, 64C.

The source electrode 10, in the active region 30, is electrically connected to the n⁺-type source regions 6 and the p⁺⁺-type contact regions 14 whose surfaces are exposed by the contact holes 64A. Further, the source electrode 10, in the edge termination region 40, is electrically connected to the p⁺⁺-type contact regions 14A whose surfaces are exposed by the contact holes 64B. Further, the metal gate runner 61 is electrically connected to the field plate 29 and the gate electrodes 8 whose surfaces are exposed by the contact hole 64C. The gate electrode pad (not depicted) is electrically connected to the metal gate runner 61 and the gate electrodes 8. In the contact holes 64A, 64B, 64C, the tungsten plugs may be embedded via the barrier metal. The contact holes 64A, 64B, 64C may be like the contact holes having the recesses similarly to the first method of manufacturing depicted in FIG. 21.

Next, by sputtering, the back electrode 11 is formed on the back surface of the n⁺-type semiconductor substrate 1 (the back surface of the semiconductor base). The back electrode 11 may be formed by, for example, a metal film containing nickel (Ni), titanium (Ti), gold (Au), silver (Ag), aluminum (Al), or an alloy containing aluminum as a main component (Al—Si, Al—Cu, Al—Si—Cu), etc. Further, a layered film of these (for example, Ti/Ni/Au, Al/Ti/Ni/Au, etc.) may be deposited as the back electrode 11. After the back electrode 11 is deposited, a heat treatment is performed, thereby forming an ohmic contact between the n⁺-type semiconductor substrate 1 and the back electrode 11. Thus, the SJ-MOSFET 50 depicted in FIG. 2B is completed.

In this manner, an impurity of the second conductivity type is ion-implanted only in regions in which the n⁻-type epitaxial layer 27 is embedded in the p-type column trenches 25B and therefore, the p-type well regions 63, 63A are not formed.

As described above, according to the embodiment, in the edge termination region 40, the n⁻-type epitaxial layer is provided and the field oxide film 13 is provided on the surface of the n⁻-type epitaxial layer 27. Due to the n⁻-type epitaxial layer 27, a depletion layer that spreads from a pn junction between the n⁻-type epitaxial layer 27 and the p⁻⁻-type RESURF region 12 spreads in the n⁻-type epitaxial layer 27, thereby enabling the breakdown voltage of the SJ-MOSFET 50 to be improved.

Further, in other embodiments, the parallel pn region 20B is provided in which the width of the n-type column regions 3B and the width of the p-type column regions 4B in the edge termination region 40 are narrower than the width of the n-type column regions 3 and the width of the p-type column regions 4 in the active region 30, whereby in the edge termination region 40, spreading of a depletion layer is facilitated and the breakdown voltage of the edge termination region 40 may be set higher than the breakdown voltage of the active region 30.

Further, the n⁻-type epitaxial layer 27 has a relatively low impurity concentration and therefore, diffusion of the p-type well regions 63, 63A and the p-type base regions 5, 5A is easily controlled and variation of the gate threshold voltage Vth may be suppressed.

Further, the p-type column regions 4 may be formed without depositing a p-type epitaxial layer like in the conventional trench embedding technique and therefore, removal of the p-type epitaxial layer at the surface by CMP equipment, etc. and formation of an n-type epitaxial layer on the surface after removal of the p-type epitaxial layer becomes unnecessary. Furthermore, a process of using CMP equipment, etc. to planarize surface portions where the p-type column trenches 25B are embedded becomes unnecessary. Thus, formation of the SJ structure may be simplified and manufacturing cost may be reduced.

In the foregoing, while an instance in which MOS gate structures are provided on a first main surface of a silicon substrate is described as an example, the present invention is not limited hereto and various modifications such in the type of semiconductor (for example, silicon carbide (SiC), etc.), plane orientation of a main surface of the substrate, etc. are possible. Further, in the embodiments of the invention, while a trench-type MOSFET is described as an example, without limitation hereto, the invention is further applicable to semiconductor devices of various configurations such as planar-type MOSFET superjunction semiconductor devices, insulated gate bipolar transistor (IGBT) superjunction semiconductor devices. Further, in the embodiments of the invention, while the first conductivity type is assumed to be an n-type and the second conductivity type is assumed to be a p-type, the present invention is similarly implemented when the first conductivity type is a p-type and the second conductivity type is an n-type.

According to the embodiments described above, in the edge termination region, the n⁻-type epitaxial layer (second semiconductor layer of the first conductivity type) is provided and the field oxide film is provided on the surface of the n⁻-type epitaxial layer. Due to the n⁻-type epitaxial layer, a depletion layer that spreads from a pn junction between the n⁻-type epitaxial layer and the p⁻⁻-type RESURF region spreads through the n⁻-type epitaxial layer and therefore, the breakdown voltage of the SJ-MOSFET may be improved. Further, the n⁻-type epitaxial layer has a relatively low impurity concentration and therefore, control of the concentration of p-type base regions by ion implantation is facilitated and variation of the gate threshold voltage Vth may be suppressed.

Further, the p-type column trenches are formed in regions that are to become the p-type column regions, the n⁻-type epitaxial layer having an impurity concentration lower than the impurity concentration of the n-type drift layer that becomes the n-type column regions is deposited, and a p-type impurity is ion-implanted from the surface of the n⁻-type epitaxial layer, whereby the p-type column regions 4 and the p-type well regions are formed. As a result, the p-type column regions may be formed without depositing a p-type epitaxial layer and therefore, removal of the p-type epitaxial layer in the edge termination region becomes unnecessary. Further, a process of using CMP equipment, etc. to planarize surface portions where the p-type column trenches are embedded becomes unnecessary. Thus, formation of the SJ structure may be simplified and manufacturing cost may be reduced.

The superjunction semiconductor device and the method of manufacturing a superjunction semiconductor device according to the invention achieve an effect in that formation of a SJ structure may be simplified and manufacturing cost may be reduced.

As described above, the superjunction semiconductor device and the method of manufacturing a superjunction semiconductor device according to the invention are useful for high-voltage semiconductor devices used in power converting equipment, power source devices such as in various types of industrial machines, etc.

Although the invention has been described with respect to a specific embodiment for a complete and clear disclosure, the appended claims are not to be thus limited but are to be construed as embodying all modifications and alternative constructions that may occur to one skilled in the art which fairly fall within the basic teaching herein set forth.

What is claimed is:

1. A method of manufacturing a superjunction semiconductor device having an active region through which a current flows, and
a termination structure region disposed at an outer periphery of the active region,
the method comprising:
preparing a semiconductor substrate of a first conductivity type, the semiconductor substrate having a first surface and a second surface opposite to each other;
forming a first semiconductor layer of the first conductivity type on the first surface of the semiconductor substrate, the first semiconductor layer having an impurity concentration lower than an impurity concentration of the semiconductor substrate;
forming a plurality of first trenches from a surface of the first semiconductor layer;
forming a second semiconductor layer of the first conductivity type on the surface of the first semiconductor layer and in the first trenches, the second semiconductor layer having an impurity concentration lower than the impurity concentration of the first semiconductor layer;
implanting an impurity of a second conductivity type in the second semiconductor layer, thereby forming
a plurality of well regions of the second conductivity type, and
a parallel pn structure including a plurality of first columns of the first conductivity type and a plurality of second columns of the second conductivity type, the first columns and the second columns alternating one another repeatedly in a direction parallel to the first surface of the semiconductor substrate, each of the second columns having a top surface in contact with a bottom surface of one of the well regions;
forming a plurality of second trenches each penetrating through the second semiconductor layer and reaching one of the first columns;
forming a plurality of second semiconductor regions of the second conductivity type each in one of the well regions on a surface thereof and in the active region;
forming a gate insulating film and a gate electrode in each of the second trenches; and
selectively forming a plurality of first semiconductor regions of the first conductivity type in the second semiconductor regions of the active region, each first semiconductor region being formed in one of the second semiconductor regions at a surface thereof.

2. The method according to claim 1, wherein
the second semiconductor regions are formed so that bottom surfaces thereof are farther from the semiconductor substrate than are bottoms surfaces of the well regions.

3. The method according to claim 1, wherein
the second semiconductor regions are formed so that an impurity concentration of the well regions is lower than an impurity concentration of the second semiconductor regions.

4. The method according to claim 1, wherein
forming the parallel pn structure includes implanting the impurity of the second conductivity type in the second semiconductor layer at portions thereof in the first trenches.

5. The method according to claim 1, wherein
forming the parallel pn structure includes implanting the impurity of the second conductivity type in the second semiconductor layer at portions thereof on the first semiconductor layer.

6. The method according to claim 1, wherein
forming the parallel pn structure includes forming the second columns in both the active region and the termination structure region.

7. The method according to claim 1, wherein
the second semiconductor regions are formed before the second trenches are formed.

8. The method according to claim 1, wherein
forming the parallel pn structure includes implanting the impurity of the second conductivity type in the second semiconductor layer only at portions thereof in the first trenches.

9. A superjunction semiconductor device having an active region through which a current flows, and
a termination structure region disposed at an outer periphery of the active region,
the superjunction semiconductor device comprising:
a semiconductor substrate of a first conductivity type, having a first surface and a second surface opposite to each other;
a first semiconductor layer of the first conductivity type, provided on the first surface of the semiconductor substrate, the first semiconductor layer having an impurity concentration lower than an impurity concentration of the semiconductor substrate;
a parallel pn structure provided in the first semiconductor layer, the parallel pn structure including a plurality of first columns of the first conductivity type and a plurality of second columns of a second conductivity type, the first columns and the second columns alternating one another repeatedly in a direction parallel to the first surface of the semiconductor substrate;
a plurality of well regions of the second conductivity type provided in the first semiconductor layer, each of the well regions having
a bottom surface in contact with a top surface of one of the second columns, and
a top surface having a width greater than a width of each of the second columns;
a plurality of second semiconductor regions of the second conductivity type, each provided in one of the well regions at a surface thereof and in the active region, bottom surfaces of the second semiconductor regions being farther from the semiconductor substrate than are the bottom surface of the well regions;
a plurality of first semiconductor regions of the first conductivity type, selectively provided in the second semiconductor regions at a surface thereof;
a plurality of trenches each penetrating through one of the first semiconductor regions and one of the second semiconductor regions, and reaching one of the first columns; and
a plurality of gate electrodes each provided in one of the trenches, via a gate insulating film.

10. The superjunction semiconductor device according to claim 9, wherein
the well regions have an impurity concentration lower than an impurity concentration of the second semiconductor regions.

11. The superjunction semiconductor device according to claim 9, wherein
the parallel pn structure is provided in both the active region and the termination structure region.

12. The superjunction semiconductor device according to claim 11, wherein
the parallel pn structure has a first repetition pitch in the termination structure region and a second repetition pitch in the active region, the first repetition pitch being narrower than the second repetition pitch.

13. The superjunction semiconductor device according to claim 9, further comprising
a second semiconductor layer of the first conductivity type, provided on a surface of the first semiconductor layer in the termination structure region, on a first side of the first semiconductor layer, which is opposite to a second side thereof facing the semiconductor substrate, the second semiconductor layer having an impurity concentration lower than the impurity concentration of the first semiconductor layer.

14. The superjunction semiconductor device according to claim 9, wherein
both the well regions and the second semiconductor regions are in contact with sidewalls of the trenches.
